(19) United States
(12) Patent Application Publication
(10) Pub. No.: US 2024/0113259 A1
(43) Pub. Date: Apr. 4, 2024

(54) LIGHT-EMITTING DEVICE

(71) Applicant: XIAMEN SAN’AN OPTOELECTRONICS CO., LTD., Xiamen (CN)

(72) Inventors: Xiushan ZHU, Xiamen (CN); Qi JING, Xiamen (CN); Yan LI, Xiamen (CN); Xiaoliang LIU, Xiamen (CN); Zhilong LU, Xiamen (CN); Chunhsien LEE, Xiamen (CN); Chi-Ming TSAI, Wuhu (CN); Juchin TU, Xiamen (CN); Chung-Ying CHANG, Xiamen (CN)

(21) Appl. No.: 18/477,021

(22) Filed: Sep. 28, 2023

(30) Foreign Application Priority Data
Sep. 30, 2022 (CN) 202211211499.1
Dec. 23, 2022 (CN) 202211661864.9
Dec. 23, 2022 (CN) 202211661950.X

(51) Int. Cl. H01L 33/20; H01L 33/38

(52) U.S. Cl. CPC H01L 33/20; H01L 33/38

(57) ABSTRACT

A light-emitting device includes a semiconductor epitaxial structure including a first semiconductor layer, an active layer, and a second semiconductor layer, and having holes; a first insulation layer disposed on the semiconductor epitaxial structure and having first and second grooves; a first pad electrically connected to the first semiconductor layer through the first grooves; and a second pad electrically connected to the second semiconductor layer through the second grooves. A projection of the first pad does not overlap projections of the holes. A projection of the second pad does not overlap the projections of the holes. The first pad includes a first pad connection portion and first pad extension portions; the second pad includes a second pad connection portion and second pad extension portions. Projections of the second grooves fall between projections of the first and second pad extension portions. Two other aspects of the light-emitting device are also provided.

### CROSS-REFERENCE TO RELATED APPLICATION

This application claims priority to Chinese Invention Patent Application No. 202211211499.1, filed on Sep. 30, 2022, Chinese Invention

Patent Application No. 202211661864.9, filed on Dec. 23, 2023, and Chinese Invention Patent Application No. 202211661950.X, filed on Dec. 23, 2023. Each of the Chinese Invention Patent Applications is incorporated herein by reference in its entirety.

### FIELD

The disclosure relates to a semiconductor device, and more particularly to a light-emitting device.

### BACKGROUND

A light-emitting device has the advantages of low cost, high luminous efficiency, energy saving, etc., and is widely used in vehicles, backlights, plant lighting, and high power lighting. Due to requirements such as high driving current, fast heat dissipation, low internal chip resistance, or high reflectivity in yellow/red light, a metal reflection layer often uses silver (Ag) for its main material because silver has high reflectivity.

### SUMMARY

Therefore, an object of the disclosure is to provide a light-emitting device that can alleviate at least one of the drawbacks of the prior art.

According to a first aspect of the disclosure, the light-emitting device includes a semiconductor epitaxial structure, a first insulation layer, a first pad, and a second pad.

The semiconductor epitaxial structure includes a first semiconductor layer, an active layer, and a second semiconductor layer sequentially stacked in such order in a laminating direction, and has a plurality of holes penetrating the second semiconductor layer and the active layer and exposing a portion of the first semiconductor layer.

The first insulation layer is disposed on the semiconductor epitaxial structure, and that has a plurality of first grooves and a plurality of second grooves. The first grooves expose the portion of the first semiconductor layer.

The first pad is formed on the semiconductor epitaxial structure and is electrically connected to the first semiconductor layer through the first grooves. A projection of the first pad on an imaginary plane perpendicular to the laminating direction does not overlap projections of the holes on the imaginary plane. The second pad is formed on the semiconductor epitaxial structure and is electrically connected to the second semiconductor layer through the second grooves. A projection of the second pad on the imaginary plane does not overlap the projections of the holes on the imaginary plane.

The first pad includes a first pad connection portion and a plurality of first pad extension portions extending from the first pad connection portion toward the second pad, and the second pad includes a second pad connection portion and a plurality of second pad extension portions extending from the second pad connection portion toward the first pad. Projections of the second grooves on the imaginary plane fall between projections of the first pad extension portions and projections of the second pad extension portions on the imaginary plane.

According to a second aspect of the disclosure, the light-emitting device includes a semiconductor epitaxial structure, a metal layer, a first insulation layer, a first connection electrode, a second connection electrode, a second insulation layer, a first pad, and a second pad.

The semiconductor epitaxial structure includes a first semiconductor layer, an active layer, and a second semiconductor layer sequentially stacked in such order in a laminating direction, and has a plurality of holes penetrating the second semiconductor layer and the active layer and exposing a portion of the first semiconductor layer.

The metal layer is formed on the second semiconductor layer. The first insulation layer is disposed on the semiconductor epitaxial

structure, and has a plurality of first grooves and a plurality of second grooves. The first grooves expose the portion of the first semiconductor layer, and the second groove expose a part of the metal layer.

The first connection electrode is formed on the first insulation layer and extends into the first grooves to be electrically connected to the first semiconductor layer.

The second connection electrode extends into the second grooves to be electrically connected to the metal layer.

The second insulation layer is formed on the first connection electrode and the second connection electrode, and has a third groove and a fourth groove.

The first pad is disposed in the third groove and is electrically connected to the first semiconductor layer.

The second pad is disposed in the fourth groove and is electrically connected to the second semiconductor layer.

Projections of the first pad and the second pad on an imaginary plane perpendicular to the laminating direction respectively do not overlap projections of the first grooves and the second grooves on the imaginary plane, and the projections of the second grooves on the imaginary plane fall within a projection of the second connection electrode on the imaginary plane.

According to a third aspect of the disclosure, the light-emitting device includes a semiconductor epitaxial structure, a first insulation layer, a first connection electrode, a second connection electrode, a first pad, and a second pad.

The semiconductor epitaxial structure includes a first semiconductor layer, an active layer, and a second semiconductor layer sequentially stacked in such order in a laminating direction, and has a plurality of holes penetrating the second semiconductor layer and the active layer and exposing a portion of the first semiconductor layer.

The first insulation layer is disposed on the semiconductor epitaxial structure, and has a plurality of first grooves and a plurality of second grooves. The first grooves penetrate the first insulation layer to expose the first semiconductor layer. The second grooves are formed on the second semiconductor layer and are separated from each other. Projections of the second grooves on an imaginary plane perpendicular to the laminating direction are located at a center line of the light-emitting device.

The first connection electrode is disposed on the first insulation layer and extends into the first grooves to be electrically connected to the first semiconductor layer.

The second connection electrode is disposed on the first insulation layer and is electrically connected to the second semiconductor layer. The first connection electrode and the second connection electrode are separated from each other by a fifth groove.

The first pad is disposed on the semiconductor epitaxial structure and is electrically connected to the first semiconductor layer through the first grooves. A projection of the first pad on an imaginary plane perpendicular to the laminating direction does not overlap projections of the holes on the imaginary plane.

The second pad is disposed on the semiconductor epitaxial structure and is electrically connected to the second semiconductor layer through the second grooves, and a projection of the second pad on the imaginary plane does not overlap the projections of the holes on the imaginary plane.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic top view illustrating an embodiment of a light-emitting device according to a first aspect of the disclosure.

FIG. 2 is a schematic cross-sectional view taken along line A-A of FIG. 1.

FIG. 3 is a schematic partial enlarged view of an area B in FIG. 1.

FIGS. 4 to 18 are schematic views illustrating various embodiments of the light-emitting device according to the first aspect of the disclosure.

FIGS. 19 to 56 are schematic views illustrating various embodiments of the light-emitting device according to a second aspect of the disclosure.

FIGS. 57 to 71 are schematic views illustrating various embodiments of the light-emitting device according to a third aspect of the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

In the description of the present disclosure, it should also be noted that, unless otherwise specified or explicitly stated, the terms “disposed,” “installed,” “mounted,” “connected,” “coupled” and the like should be understood in a broad sense. For example, a “connection” may be a fixed connection, but it may also be a detachable connection or an integral connection; it may be a mechanical connection or an electrical connection; it may be a direct connection or an indirect connection achieved through an intermediary, or it may refer to internal communication of two components. The above terms as used in the present disclosure are intended to be understandable to one of ordinary skill in the art under the specific situations as described in the disclosure. Furthermore, the terms “first” and “second,” etc., are used only for descriptive purposes and are not to be understood as indicating or implying relative importance.

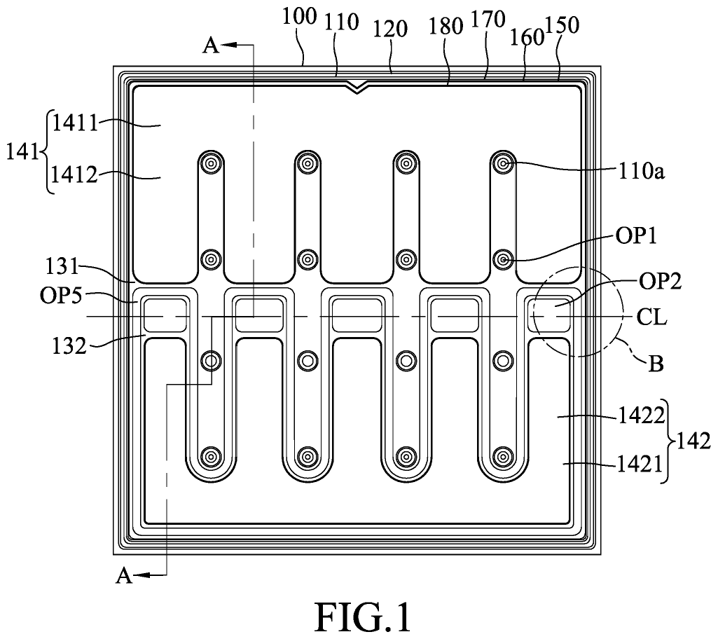

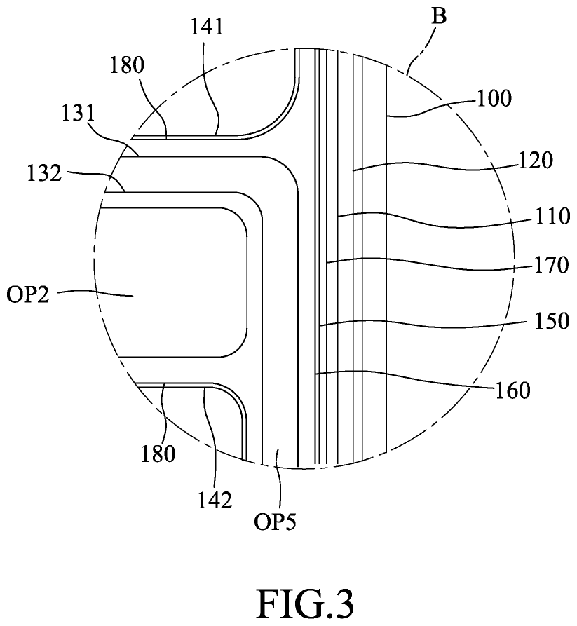

Referring to FIGS. 1 to 3, an embodiment of a light-emitting device according to the disclosure includes a substrate 100, a semiconductor epitaxial structure 110 disposed on substrate 100 and having a plurality of holes 110a, a first insulation layer 120 disposed on the semiconductor epitaxial structure 110, and a first pad 141 and a second pad 142 disposed on the first insulation layer 120.

The semiconductor epitaxial structure 110 includes a first semiconductor layer 111, an active layer 112, and a second semiconductor layer 113 sequentially stacked on the substrate 100 in such order in a laminating direction. The holes 110a are respectively defined by hole-defining walls and extend downward from predetermined locations of a top surface of the second semiconductor layer 113 through the second semiconductor layer 113 and the active layer 112 to expose a portion of the first semiconductor layer 111.

The first insulation layer 120 is disposed on and covers a top surface of the semiconductor epitaxial structure 110, a side wall (in a step form in this embodiment) of the semiconductor epitaxial structure 110, and a part of a surface of the substrate 100 proximate to the semiconductor epitaxial structure 110. The first insulation layer 120 is also formed on the hole-defining walls. The first insulation layer 120 has a plurality of first grooves (OP1) and a plurality of second grooves (OP2). Each of the first grooves (OP1) is located in a center portion of a respective one of the holes 110a and partly exposes the portion of the first semiconductor layer 111 exposed from the holes 110a.

The first pad 141 and the second pad 142 are formed on the semiconductor epitaxial structure 110. The first pad 141 is electrically connected to the first semiconductor layer 111 through the first grooves (OP1). The second pad 142 is electrically connected to the second semiconductor layer 113 through the second grooves (OP2). Projections of the first and second pads 141, 142 on an imaginary plane perpendicular to the laminating direction do not overlap projections of the holes 110a and the first and second grooves (OP1, OP2) on the imaginary plane, so that a bonding area between a packaging substrate and the first pad 141 and a bonding area between the packaging substrate and the second pad 142 may be increased during subsequent packaging.

The first pad 141 further includes a first pad connection portion 1411 and a plurality of first pad extension portions 1412 extending from the first pad connection portion 1411 toward the second pad 142. The second pad 142 includes a second pad connection portion 1421 and a plurality of second pad extension portions 1422 extending from the second pad connection portion 1421 toward the first pads 141. The projections of the second grooves (OP2) on the imaginary plane fall between projections of the first pad extension portions 1412 and projections of the second pad extension portions 1422 on the imaginary plane. Each of the first pad extension portions 1412 has a width greater than a width of each of the second pad extension portions 1422.

The second pad connection portion 1421 is electrically connected to the second semiconductor layer 113 through the second grooves (OP2) so as to expand an injection area of current, to enhance current spreading ability and resistance to large driving current, and to reduce current crowding. By disposing the second grooves (OP2) between the first pad 141 and the second pad 142, transmission path of current may be shortened when current is injected, thereby further reducing current crowding.

In one embodiment, the substrate 100 is a growth substrate for the semiconductor epitaxial structure 110, and may be made of a conductive material, an insulating material, or a light transmissive material having excellent thermal conductivity. The substrate 100 may be a sapphire substrate, a silicon carbide substrate, a gallium nitride substrate, a zinc oxide substrate, a silicon substrate, a gallium arsenide substrate, or a gallium phosphide substrate. In some embodiments, the substrate 100 is a sapphire substrate.

In certain embodiments, the substrate 100 may be removed by a separation technique such as laser lift-off (LLO) or chemical lift-off (CLO) in a subsequent process.

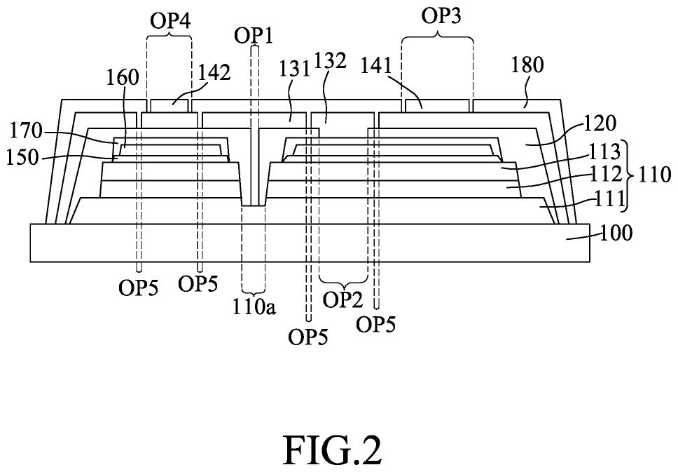

Referring to FIG. 2, in one embodiment, the semiconductor epitaxial structure 110 may be formed on the substrate 100 by a method such as metal organic chemical vapor deposition (MOCVD), hydride vapor phase epitaxy (HYPE), molecular beam epitaxy (MBE), etc. The first semiconductor layer 111, the active layer 112, and the second semiconductor layer 113 include group III compound semiconductors, e.g., GaN, AlN, InGaN, AlGaN, InAlGaN, or combinations thereof. In this embodiment, the first semiconductor layer 111 is disposed on and connected to the substrate 100, and may be doped with an N-type dopant, such as Si, Ge, Se, Te, C, or the like, to provide electrons. The second semiconductor layer 113 may be doped with a P-type dopant, such as Mg, Zn, Be, Ca, Sr, Ba, or the like, to provide holes. The active layer 112 is disposed between the first semiconductor layer 111 and the second semiconductor layer 113. The active layer 112 is a region for the electrons and the holes to recombine for light emitting, may have well layers and barrier layers alternatively stacked, or may have a multiple quantum well structure.

When the light-emitting device is not being applied with a voltage, a PN junction having a higher barrier is formed between the first semiconductor layer 111 and the second semiconductor layer 113, thereby preventing the electrons in the first semiconductor layer 111 from diffusing into the second semiconductor layer 113, and the holes in the second semiconductor layer 113 from diffusing into the first semiconductor layer 111. However, when a forward bias (i.e., a working voltage) is applied to the light-emitting device, the barrier at the PN junction decreases, so the electrons in the first semiconductor layer 111 and the holes in the second semiconductor layer 113 may migrate and diffuse to each other. Then, the electrons and the holes are recombined in the active layer 112, and energy is released in the form of light, thereby achieving light emitting.

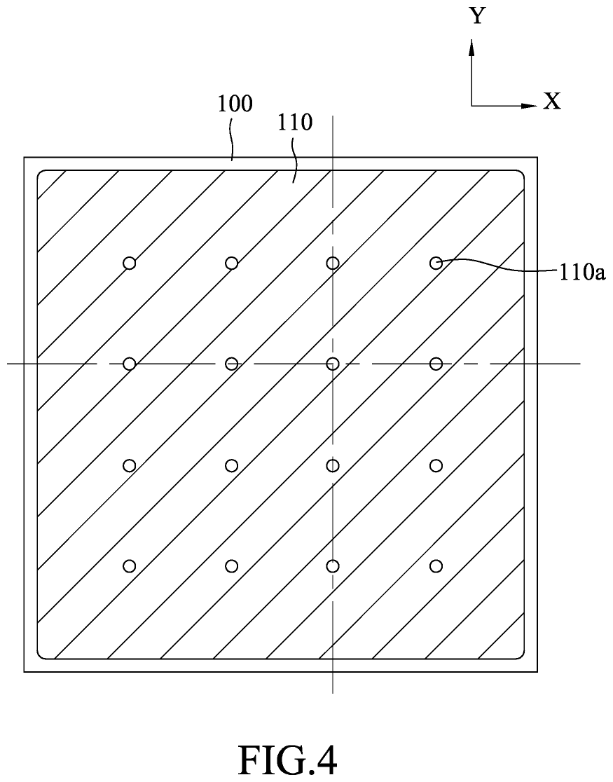

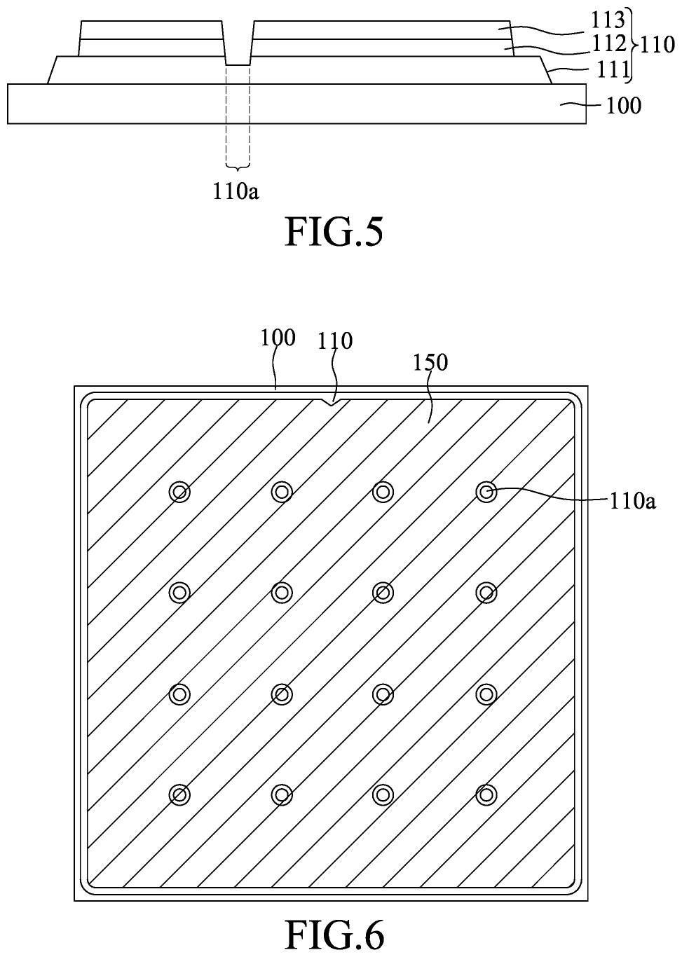

Referring to FIGS. 4 and 5, in certain embodiments, in a direction (i.e., a horizontal direction) perpendicular to the laminating direction, each of the holes 110a may have a cross section that is a circle, a rectangle, or a hexagon, but is not limited to. The holes 110a may be distributed in a uniform or non-uniform manner. In this embodiment, the cross section of each of the holes 110a is a circle, and the holes 110a are arranged such that they are spaced apart evenly.

The light-emitting device further includes a first connection electrode 131 formed on the first insulation layer 120 and extends into the first grooves (OP1) to be electrically connected to the first semiconductor layer 111, and a second connection electrode 132 formed on the first insulation layer 120 and extends into the second grooves (OP2) to be electrically connected to the second semiconductor layer 113. The first pad 141 is electrically connected to the first semiconductor layer 111 through the first connection electrode 131, and the second pad 142 is electrically connected to the second semiconductor layer 113 through the second connection electrode 132. When power is turned on, an external current passes through the first connection electrode 131 in the hole 110a to be electrically connected to the first semiconductor layer 111. The plurality of holes 110a that are distributed evenly may enhance current spreading and uniformity of current distribution, and may increase a contact area between the first connection electrode 131 and the first semiconductor layer 111, thereby reducing the voltage and enhancing luminous efficiency of the light-emitting device.

Referring to FIGS. 1 and 4, in some embodiments, the holes 110a are distributed in a first direction (X) and a second direction (Y) that is perpendicular to the first direction (X) to form a matrix. The first pad connection portion 1411 extends in the first direction (X), and the first pad extension portions 1412 extend from the first pad connection portion 1411 toward the second metal pad 142 in the second direction (Y). The holes 110a form a plurality of rows in the first direction (X) and a plurality of columns in the second direction (Y). The second grooves (OP2) do not overlap the rows and the columns of the holes 110a, and are not intersected by any of the rows or the columns. It should be noted that defining the first direction (X) and the second direction (Y) is merely for convenience of description and is not intended to limit orientations of the first pad connection portion 1411 and the first pad extension portions 1412.

In certain embodiments, the holes 110a formed in the second direction (Y) are located between the second pad extension portions 1422. That is, the columns of the holes 110a are located between the second pad extension portions 1412.

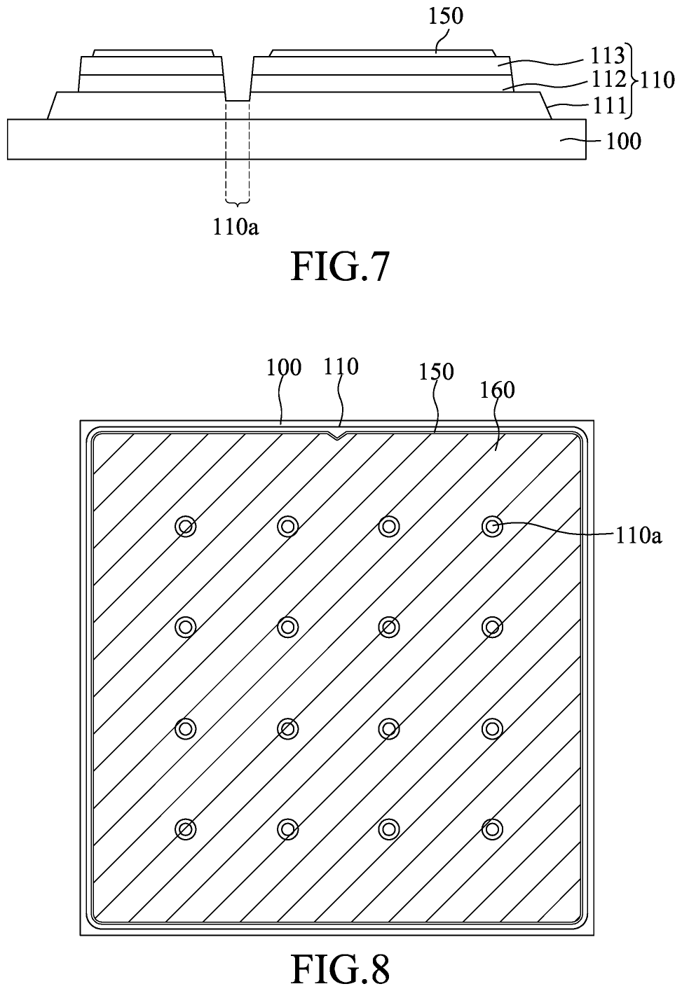

Referring to FIGS. 2, 6 and 7, in certain embodiments, the light-emitting device further includes a transparent conductive layer 150. The transparent conductive layer 150 is formed on the second semiconductor layer 113 by physical vapor deposition or chemical vapor deposition, and is in ohmic contact with the second semiconductor layer 113 for dispersing the externally injected current along a horizontal direction to the top surface of the second semiconductor layer 113 in contact therewith. Each of the transparent conductive layer 150 and the second semiconductor layer 113 does not cover the holes 110a. The transparent conductive layer 150 has an excellent light transmitting property. When light emitted by the active layer 112 passes through the transparent conductive layer 150, the light does not lose energy substantially. Materials of the transparent conductive layer 150 may include indium tin oxide, indium tin zinc oxide, zinc tin oxide, gallium indium tin oxide, indium gallium oxide, fluorine-doped tin oxide, aluminum-doped zinc oxide, etc.

In certain embodiments, a projection of the transparent conductive layer 150 on the imaginary plane falls within a projection of the second semiconductor layer 113 on the imaginary plane, and the projection of the transparent conductive layer 150 occupies 80% to 95% of the projection of the second semiconductor layer 113. By increasing a contact area between the transparent conductive layer 150 and the second semiconductor layer 113, the externally injected current may be more uniformly transferred onto the top surface of the second semiconductor layer 113, thereby further reducing the voltage. By virtue of the projection of the transparent conductive layer 150 falling within the projection of the second semiconductor layer 113 on the imaginary plane, the transparent conductive layer 150 does not extend into the holes 110a and onto the side wall of the semiconductor epitaxial structure 110, thereby preventing a short circuit caused by a direct contact between the first semiconductor layer 111 and the second semiconductor layer 113.

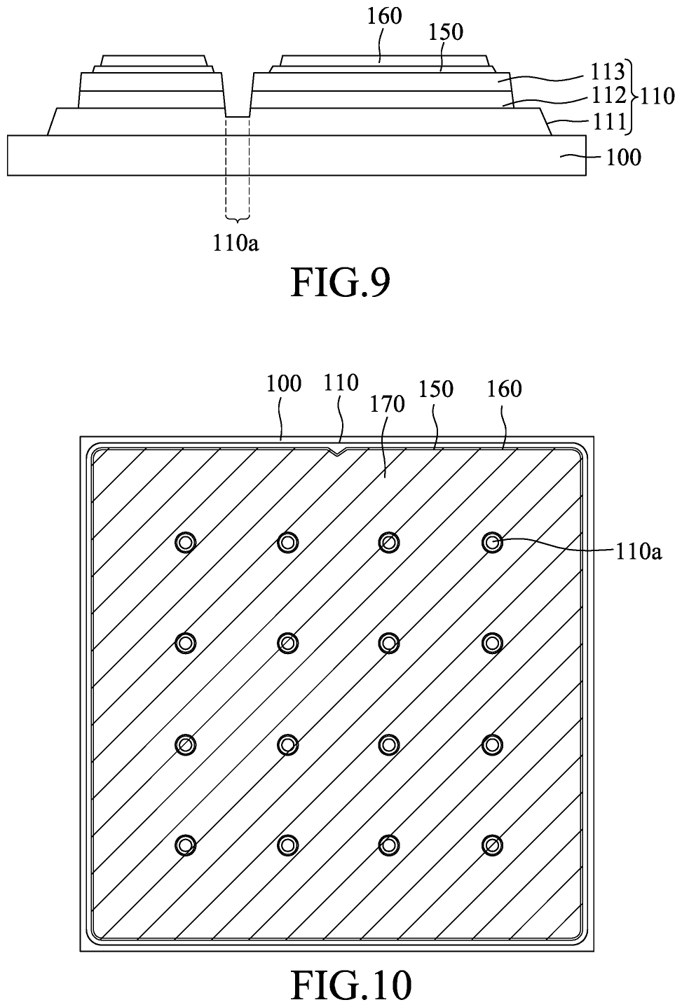

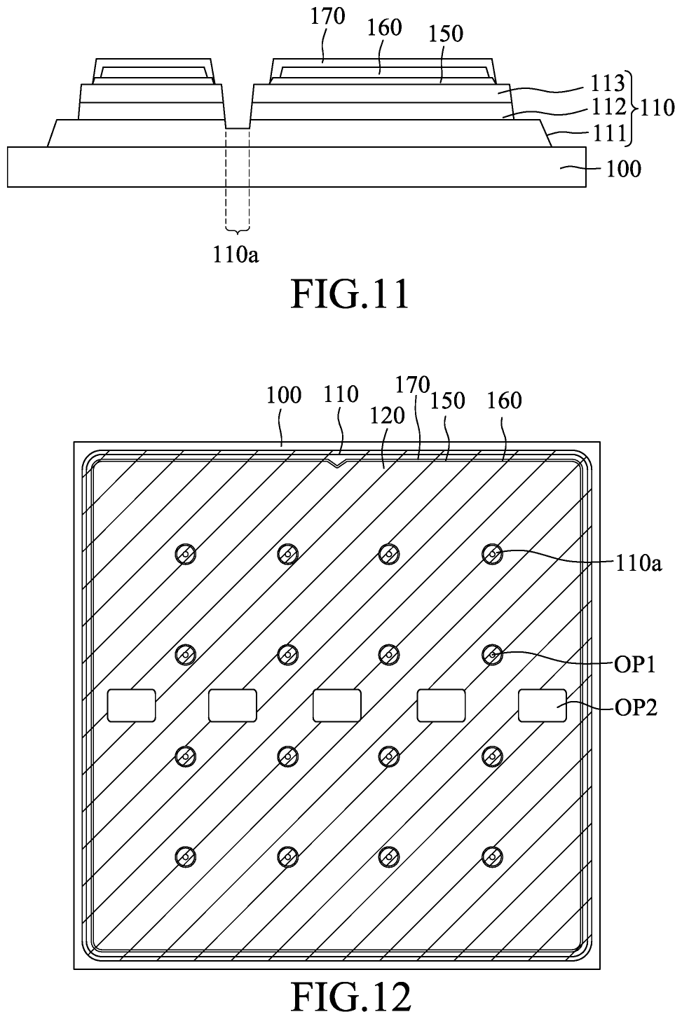

Referring to FIGS. 8 to 11, in certain embodiments, the light-emitting device further includes a metal layer that includes a reflection layer 160 and a barrier layer 170. The reflection layer 160 is disposed on the transparent conductive layer 150 for reflecting the light so as to further improve light extraction efficiency of the light-emitting device. The reflection layer 160 forms an ohmic contact with the transparent conductive layer 150 to spread current passing through the transparent conductive layer 150 to the second semiconductor layer 113. The barrier layer 170 is disposed on the reflection layer 160 and covers a side wall of the reflection layer 160 to prevent oxidation of the reflection layer 160 as oxidation may cause deterioration of reflectivity of the reflection layer 160. At the same time, the barrier layer 170 may block ion migration of the reflection layer 160. The side wall of the reflection layer 160 may or may not align with a side wall of the transparent conductive layer 150. The first insulation layer 120 covers the barrier layer 170 and exposes a portion of the barrier layer 170 at the second grooves (OP2), and the second connection electrode 132 extends into the second grooves (OP2) to be electrically connected to the barrier layer 170.

In some embodiments, a projection of the reflection layer 160 on the imaginary plane falls within the projection of the transparent conductive layer 150 on the imaginary plane. That is to say, the side wall of the reflection layer 160 fall inside the side wall of the transparent conductive layer 150, so as to further increase the contact area between the transparent conductive layer 150 and the second semiconductor layer 113, thereby reducing the voltage. The barrier layer 170 covers the side wall of the reflection layer 160, and a projection of the barrier layer 170 on the imaginary plane falls within the projection of the transparent conductive layer 150 on the imaginary plane. In other words, projections of the transparent conductive layer 150, the reflection layer 160, and the barrier layer 170 on the imaginary plane all fall within the projection of the second semiconductor layer 113 on the imaginary plane, and the transparent conductive layer 150, the reflection layer 160, and the barrier layer 170 do not cover the holes 110a. Each of the reflection layer 160 and the barrier layer 170 is made of a metal material. The reflection layer 160 may be made of one of Ag, Al, Ti, W, Ni, or combinations thereof, has a light reflecting property, and has a light reflectance no smaller than 90%. In certain embodiments, the reflection layer 160 includes a silver layer. The barrier layer 170 is made of one of Cr, Ti, Ni, Au, Al, Pt, or combinations thereof, which may block ion diffusion.

Specifically, when the reflection layer 160 includes a silver layer and when power is on, ion migration may occur due to heat or power, such that silver ions in the reflection layer 160 migrating in an orderly or unorderly manner may diffuse into the semiconductor epitaxial structure 110, thereby causing partial leakage and failure of the light-emitting device. Meanwhile, the silver layer in the reflection layer 160 is also susceptible to oxidation caused by moisture, which may cause deterioration of the reflectivity of the reflection layer 160. Therefore, the barrier layer 170 is disposed to cover a top surface and the side wall of the reflection layer 160 for protection. That is to say, a conductive combination of the transparent conductive layer 150, the reflection layer 160, and the barrier layer 170 may effectively prevent the silver ions from diffusing into the semiconductor epitaxial structure 110. The excellent conductivity of silver may reduce voltage drop of the transparent conductive layer 150, and high reflectance of silver may improve a light-emitting efficiency of the light-emitting device.

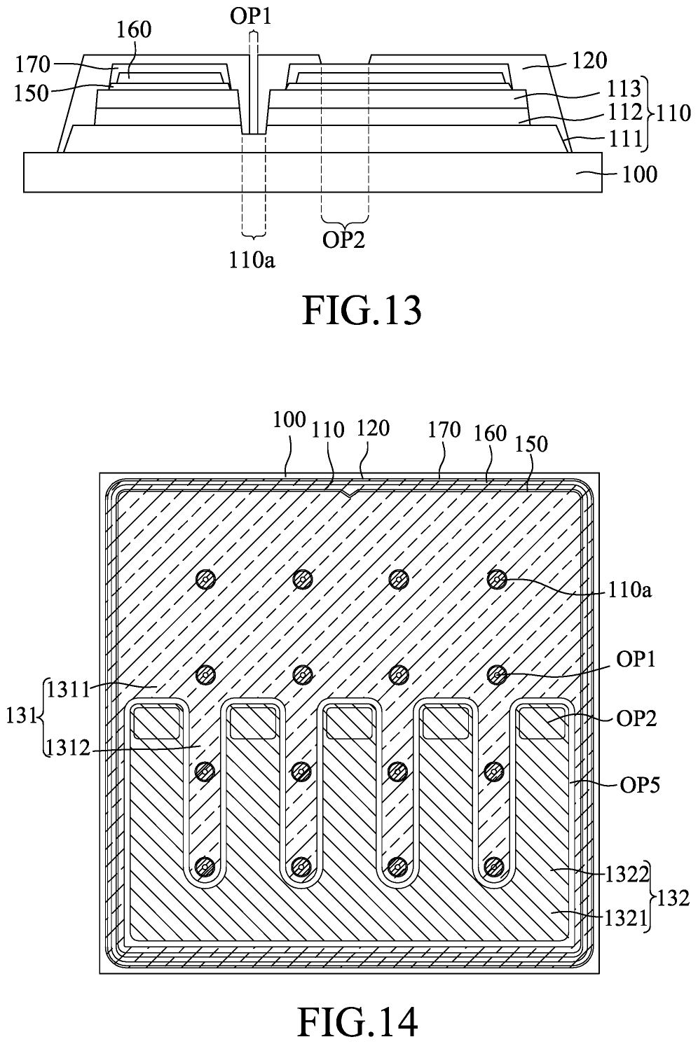

Referring to FIGS. 12 and 13, in certain embodiments, the first insulation layer 120 is formed on the barrier layer 170, and covers the side wall of the semiconductor epitaxial structure 110 and the holes 110a. Then, by photolithography and etching, the first insulation layer 120 is patterned to form the first grooves (OP1) and the second grooves (OP2).

The number of the first grooves (OP1) is the same as the number of the holes 110a. Each of the first grooves (OP1) is disposed concentrically to a respectively one of the holes 110a. The first grooves (OP1) penetrate the first insulation layer 120 to expose the portion of the first semiconductor layer 111 which allows the first connection electrode 131 being formed therein and being electrically connected to the first semiconductor layer 111.

In certain embodiments, the projection of each of the first grooves (OP1) on the imaginary plane falls within the projection of the respectively one of the holes 110a on the imaginary plane. That is to say, an opening of each of the holes 110a is to be greater than an opening of a respective one of the first grooves (OP1), so that the first connection electrode 131 which is subsequently formed may only form an electrical connection with the first semiconductor layer 111 while being electrically isolated from other conductive layers including the second semiconductor layer 113, the transparent conductive layer 150, the reflection layer 160, and the barrier layer 170 due to presence of the insulation layer 120.

In another embodiment, the second grooves (OP2) are formed on the second semiconductor layer 113 and are separated from each other. The projections of the second grooves (OP2) on the imaginary plane overlap a center line (CL) of the light-emitting device. By virtue of the second grooves (OP2) being separated from each other in the first direction (X), when the projections of the second grooves (OP2) overlap the center line (CL) of the light-emitting device, a transmission path of the current may be shortened when the current is injected, thereby further reducing current crowding. The number of the second grooves (OP2) may be the same as the number of the second pad extension portions 1422.

In some embodiments, a size of each of the second grooves (OP2) may be the same or different. A length of each of the second grooves (OP2) in the first direction (X) ranges from 120 μm to 145 μm, and a width of each of the second grooves (OP2) in the second direction (Y) ranges from 80 μm to 100 μm. For example, in this embodiment, the number of the second grooves (OP2) is five.

When viewing from the top, each of the second grooves (OP2) is a rectangular opening that has a width of 91 μm in the second direction (Y). Two of the second grooves (OP2) that are proximate to a periphery of the light-emitting device each have a length of 127 μm in the first direction (X). The three second grooves (OP2) that are in the middle of the light-emitting device has a length of 142 μm in the first direction (X). A distance between two adjacent second grooves (OP2) is 138 μm in the first direction (X). The shape, number, and size of the second grooves (OP2) are not particularly limited, and may be adjusted by those skilled in the art according to requirements.

In certain embodiments, an opening of one of the second grooves (OP2) is to further overlap a center of the light-emitting device. After the first connection electrode 130 covers the second grooves (OP2), a current may be injected into the light-emitting device through the first connection electrode 131 located in the second groove (OP2) at the center of the light-emitting device. The second groove (OP2) at the center of the light-emitting device may also prevent damage from an ejector pin, thereby further improving utilization of the light-emitting device. Since electrical property of the ejector pin is the same as that of the second connection electrode 132, leakage may not occur when the ejector pin is in contact with the second connection electrode 132 in the second grooves (OP2).

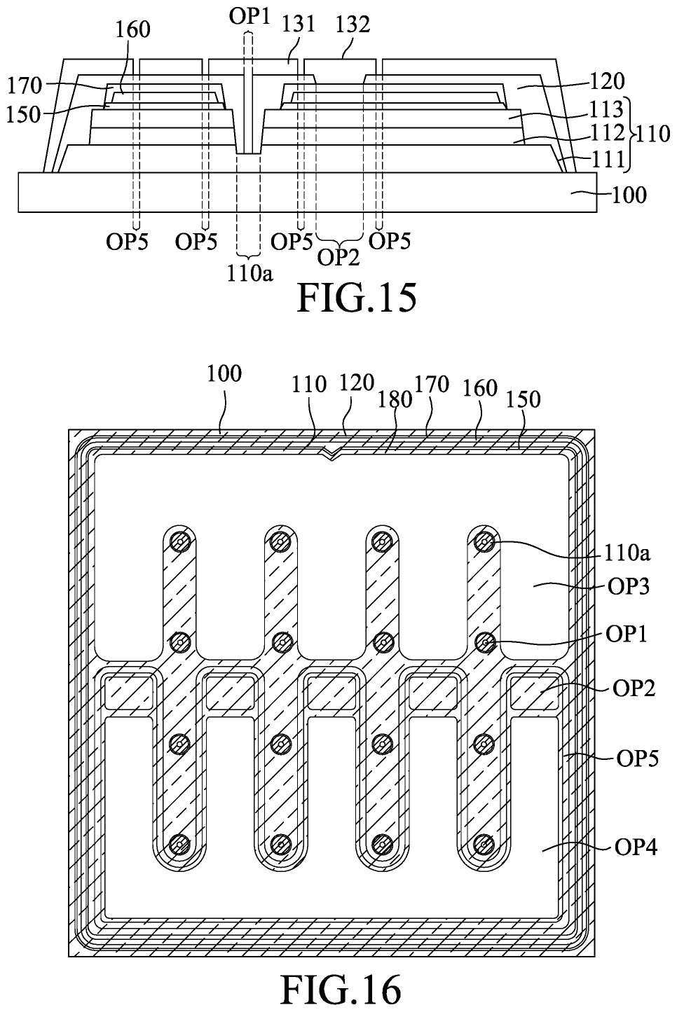

Referring to FIGS. 14 and 15, in one embodiment, the first connection electrode 131 is formed on the first insulation layer 120 and extends into the first grooves (OP1) to be electrically connected to the first semiconductor layer 111. The second connection electrode 132 is formed on the first insulation layer 120 and extends into the second grooves (OP2) to be electrically connected to the second semiconductor layer 113. Moreover, the first connection electrode 131 and the second connection electrode 132 are separated from each other by a continuous ring-shaped fifth groove (OP5), which exposes a portion of the first insulation layer 120 so as to separate the first connection electrode 131 and the second connection electrode 132 from each other.

In certain embodiments, the first connection electrode 131 includes a first electrode connection portion 1311 and a plurality of first electrode extension portions 1312 extending from the first electrode connection portion 1311 toward the second connection electrode 132, and the second connection electrode 132 includes a second electrode connection portion 1321 and a plurality of second electrode extension portions 1322 extending from the second electrode connection portion 1321 toward the first connection electrode 131. The projections of the second grooves (OP2) on the imaginary plane fall within projections of the second electrode extension portions 1322 on the imaginary plane, so that the second connection electrode 132 may fill the second grooves (OP2) to be electrically connected to the second semiconductor layer 113, and that a periphery of the second electrode extension portions 1322 may further be located at top surface of the first insulation layer 120.

In some embodiments, the first electrode extension portions 1312 do not overlap the second electrode extension portions 1322, and each of the first electrode extension portions 1312 has a width that is smaller than a width of each of the second electrode extension portion 1322, so that the second electrode extension portions 1322 may avoid covering the holes 110a, and that upper surfaces of the first connection electrode 131 and the second connection electrode 132 may be planarized.

In certain embodiments, each of the first connection electrode 131 and the second connection electrode 132 may be a single layered structure or a multilayered structure, and includes a metal material having conductivity such as Au, Ti, Ni, Al, Ag, Gr, Pt, or the like or any alloy thereof. A minimum distance between the first connection electrode 131 and the second connection electrode 132 is no smaller than 20 μm. That is to say, a minimum width of the fifth groove (OP5) is no smaller than 20 μm.

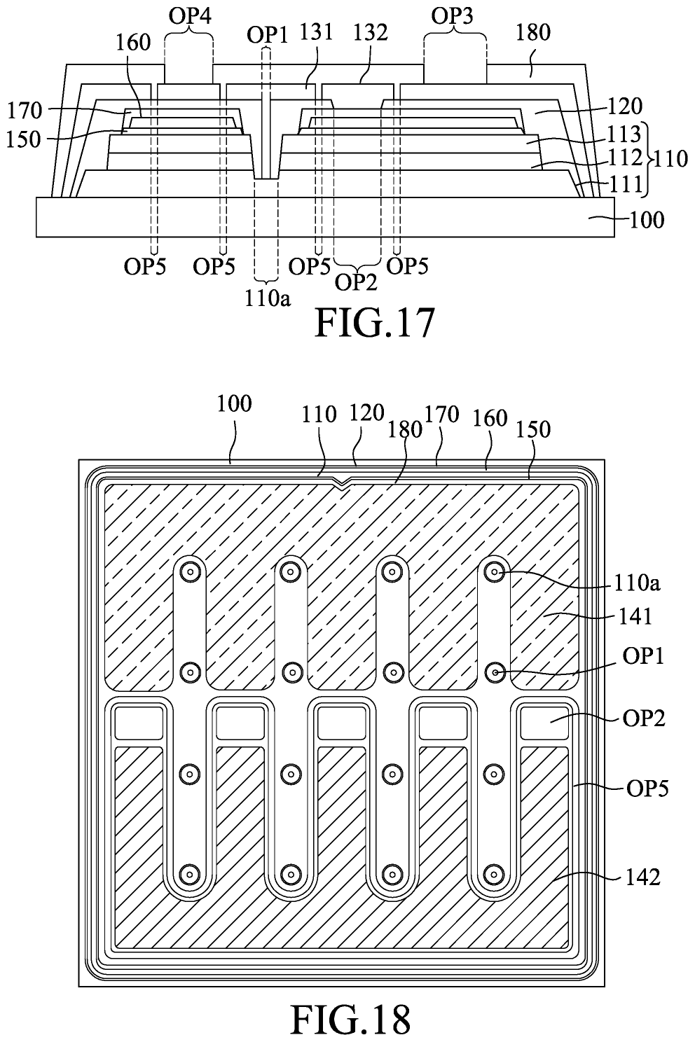

Referring to FIGS. 16 and 17, in certain embodiments, the light-emitting device further includes a second insulation layer 180 that is formed on the first connection electrode 131 and the second connection electrode 132. By photolithography and etching, the second insulation layer 180 is patterned to form the third groove (OP3) and the fourth groove (OP4). The third groove (OP3) is formed on the first connection electrode 131 and exposes a portion of the first connection electrode 131. The fourth groove (OP4) is formed on the second connection electrode 132 and exposes a portion of the second connection electrode 132. The third groove (OP3) and the fourth groove (OP4) serve as paths for external electrical connection of the light-emitting device. A greater (i.e., wider) third groove (OP3) and a greater fourth groove (OP4) may better facilitate heat dissipation of the light-emitting device.

In certain embodiments, a projection the third groove (OP3) on the imaginary plane falls within a projection of the first connection electrode 131 on the imaginary plane, and a projection the fourth groove (OP4) on the imaginary plane falls within a projection of the second connection electrode 132 on the imaginary plane.

In some embodiments, the second insulation layer 180 covers the holes 110a and fills the fifth groove (OP5), thereby further separating the first connection electrode 131 and the second connection electrode 132 from each other. Furthermore, the second insulation layer 180 also extends to cover the side wall of the semiconductor epitaxial structure 110 so as to form a protection on the first connection electrode 131 that covers the side wall of the semiconductor epitaxial structure 110.

Referring to FIG. 18, in certain embodiments, the projections of the first and second pads 141, 142 on the imaginary plane do not overlap the projections of the first and second grooves (OP1, OP2). Alternatively, the projections of the first and second pads 141, 142 on the imaginary plane do not overlap the projections of the holes 110a, thereby avoiding a short circuit between the first pad 141 and the second connection electrode 132 and a short circuit between the second metal pad 142 and the first connection electrode 131. In addition, such configuration may improve planarization of upper surfaces of the first pad 141 and the second pad 142, thereby effectively reducing the porosity and enhancing reliability of the light-emitting device during subsequent packaging.

In some embodiments, a minimum distance between the first pad 141 and a boundary of the third groove (OP3) ranges from 5 μm to 20 μm. A minimum distance between the second pad 142 and a boundary of the fourth groove (OP4) ranges from 5 μm to 20 μm. The limitations placed on these minimum distances are aimed to expand an area ratio of each the first pad 141 and the second pad 142 in the light-emitting device, so as to increase the bonding area between the packaging substrate and the first pad 141 and the bonding area between the packaging substrate and the second pad 142 in the subsequent packaging process, and to improve heat dissipation.

In some embodiments, the projection of the first pad 141 occupies 90% to 100% of the projection of the third groove (OP3) on the imaginary plane, and the projection of the second pad (142) occupies 90% to 100% of the projection of the fourth groove (OP4) on the imaginary plane.

In some embodiments, a minimum distance from each of the first pad 141 and the second pad 142 to the center line (CL) of the light-emitting device is equal, and a minimum distance between the first pad 141 and the second pad 142 is no smaller than 150 μm. By reducing the distance between the first pad 141 and the second pad 142, the areas of the first pad 141 and the second pad 142 in the light-emitting device are increased, thereby improving heat dissipation ability of the light-emitting device and optimizing the resistance to large current.

In some embodiments, each of the first pad 141 and the second pad 142 may be a single layered structure or a multilayered structure that may include a metal material having conductivity such as Au, Ti, Ni, Al, Ag, Gr, Pt, etc.

Thus, the disclosure provides the light emitting device that includes the semiconductor epitaxial structure 110, the holes 110a, the first insulation layer 120 disposed on the semiconductor epitaxial structure 110, and the first pad 141 and the second pad 142 disposed on the first insulation layer 120. The semiconductor epitaxial structure 110 includes the first semiconductor layer 111, the active layer 112, and the second semiconductor layer 113. The first insulation layer 120 includes the first grooves (OP1) and the second grooves (OP2). The first pad 141 is electrically connected to the first semiconductor layer 111 through the first grooves (OP1), and the second pad 142 is electrically connected to the second semiconductor layer 113 through the second grooves (OP2). By having the projections of the second grooves (OP2) on the imaginary plane falling between the projections of the first pad extension portions 1412 and the second pad extension portions 1422, the injection area of current is increased, the current spreading ability and resistance to large driving current are enhanced, while the transmission path of the current is shortened when the current is injected, thereby reducing current crowding.

As mentioned above, in certain embodiments, the one of the second grooves (OP2) overlaps the center of the light-emitting device. The subsequently formed second connection electrode 132 also overlaps the center of the light-emitting device. In this way, the second groove (OP2) at the center of the light-emitting device may not only be used for current injection, but to prevent the damage from the ejector pin, further improving utilization of the light-emitting device.

As mentioned above, by controlling the minimum distance between the first pad 141 and the second pad 142 to be no smaller than 150 μm and the minimum distance from each of the first pad 141 and the second pad 142 to the center line (CL) of the light-emitting device to be equal, the distance between the first pad 141 and the second pad 142 is shortened, thereby increasing the areas of the first pad 141 and the second pad 142 on the light-emitting device, and improving heat dissipation of the light-emitting device and resistance to large current.

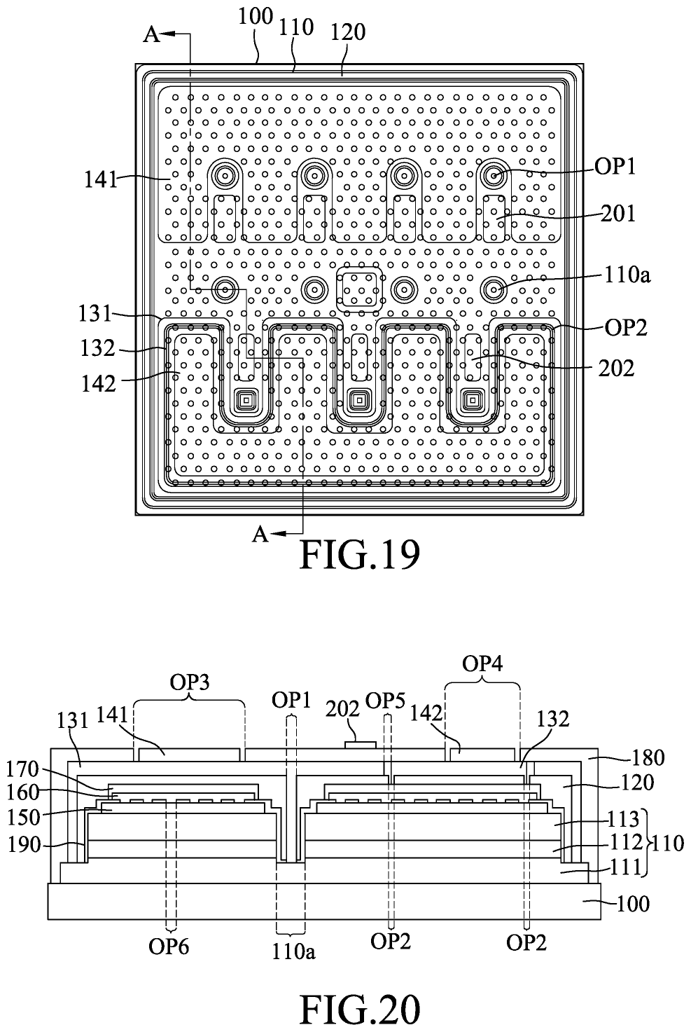

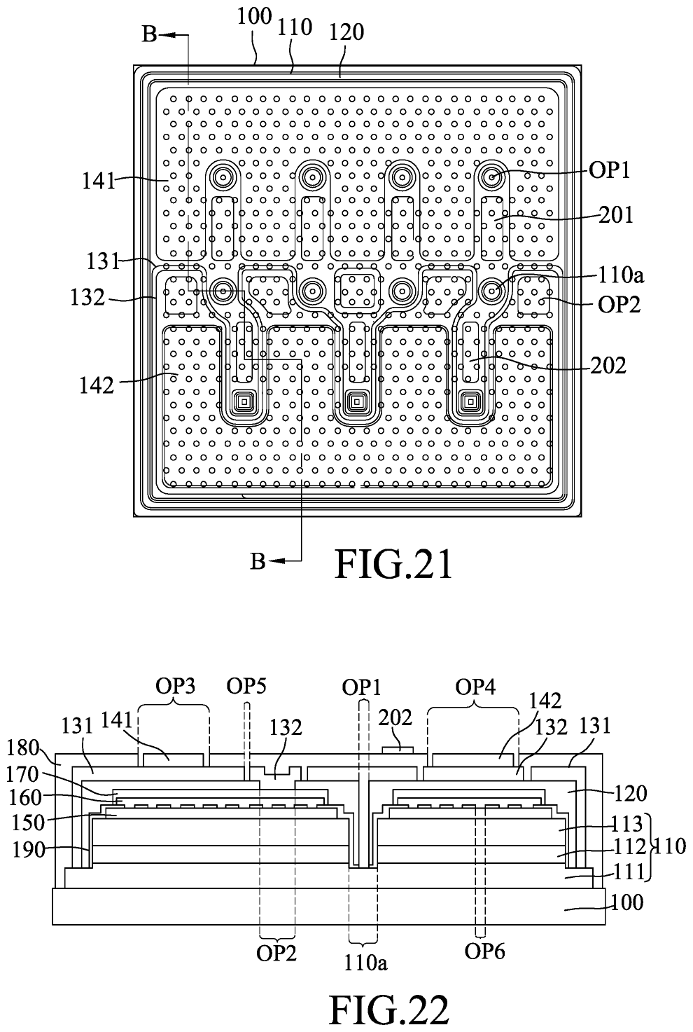

FIGS. 19 to 22 shows an embodiment of a light-emitting device according to this disclosure. Similar to the aforesaid embodiment shown in FIGS. 1 and 2, the light-emitting device includes a substrate 100, the semiconductor epitaxial structure 110 disposed on the substrate 100 and having the plurality of holes 110a, the first insulation layer 120 disposed on the semiconductor epitaxial structure 110, and the first pad 141 and the second pad 142 disposed on the first insulation layer 120.

The semiconductor epitaxial structure 110 includes the first semiconductor layer 111, the active layer 112, and the second semiconductor layer 113 sequentially stacked on the substrate 100 in such order in the laminating direction. The holes 110a are respectively defined by the hole-defining walls and extend downward from the predetermined locations of the top surface of the second semiconductor layer 113 through the second semiconductor layer 113 and the active layer 112 to expose the portion of the first semiconductor layer 111.

The first insulation layer 120 is disposed on and covers the top surface of the semiconductor epitaxial structure 110, the side wall (in the step form in this embodiment) of the semiconductor epitaxial structure 110, and the part of the surface of the substrate 100 proximate to the semiconductor epitaxial structure 110. The first insulation layer 120 is also formed on the hole-defining walls. The first insulation layer 120 has the plurality of first grooves (OP1) and at least one second groove (OP2). Each of the first grooves (OP1) is located at the center portion of the respective one of the holes 110a and partly exposes the portion of the first semiconductor layer 111 exposed from the holes 110a.

The first pad 141 and the second pad 142 are formed on the semiconductor epitaxial structure 110. The first pad 141 is electrically connected to the first semiconductor layer 111 through the first grooves (OP1). The second pad 142 is electrically connected to the second semiconductor layer 113 through the second groove (OP2). The second pad 142 includes the second pad connection portion 1421 and the plurality of second pad extension portions 1422 extending from the second pad connection portion 1421 toward the first pads 141. The projections of the second pad extension portions 1422 on the imaginary plane fall within the projection of the second connection electrode 132 on the imaginary plane, and the projections of the second grooves (OP2) do not overlap the projections of the second pad extension portions 1422.

The light-emitting device further includes a plurality of first electrode blocks 201 and a plurality of second electrode blocks 202. Each of the second electrode blocks 202 is disposed between two adjacent second pad extension portions 1422. The projection of the first pad 141, the projection of the second pad 142, the projections of the holes 110a, and projections of the second electrode blocks 202 on the imaginary plane do not overlap each other.

The second electrode blocks 202 are disposed proximate to the second pad 142. By disposing each of the second electrode blocks 202 between two adjacent second pad extension portions 1422, coverage area of metal on the surface of the light-emitting device may be increased, thereby improving heat dissipation and the reliability of the light-emitting device.

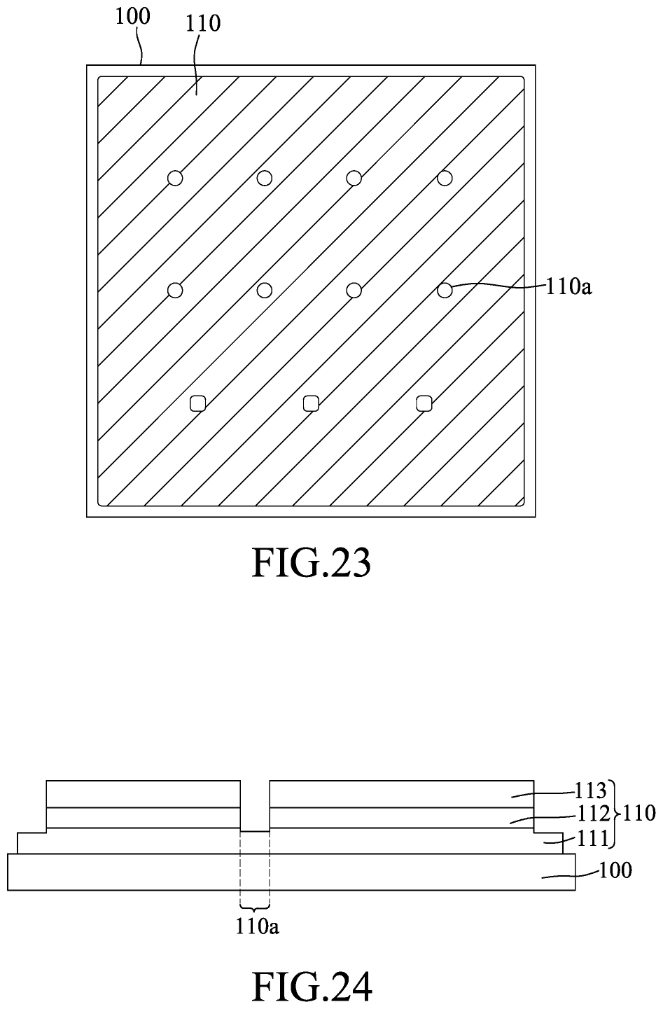

Referring to FIGS. 23 and 24, in certain embodiments, the semiconductor epitaxial structure 110 is formed on the substrate 100 by a method such as metal-organic chemical vapor deposition (MOCVD), hydride vapor phase epitaxy (HYPE), molecular beam epitaxy (MBE), etc.

In an embodiment, the cross section of each of the holes 110a is a circle, a rectangle, or a hexagon, but is not limited to. The holes 110a may be distributed in a uniform or non-uniform manner. For example, in this embodiment, cross sections of the holes 110a include circles and squares with round corners. The cross sections of the holes 110a proximate to the second pad 142 are squares with round corners, and the remaining holes 110a have cross sections that are circles. Different shapes of the holes 110a may facilitate distinguishing an area for forming the first pad 141 from an area for forming the second pad 142 in the subsequent process. When the current is injected, the holes 110a that are disposed separately from one another may enhance current spreading, thereby improving the light-emitting efficiency of the light-emitting device.

It should be noted that number and manner of distribution of the holes 110a on the semiconductor epitaxial structure 110 may vary according to the size of the light-emitting device. When the size of the light-emitting device is greater, the number of the holes 110a is greater so as to ensure the voltage requirement. For example, in this embodiment, the holes 110a proximate to the first pad 141 and the holes 110a proximate to the second pad 142 are arranged asymmetrically relative to the center line (CL).

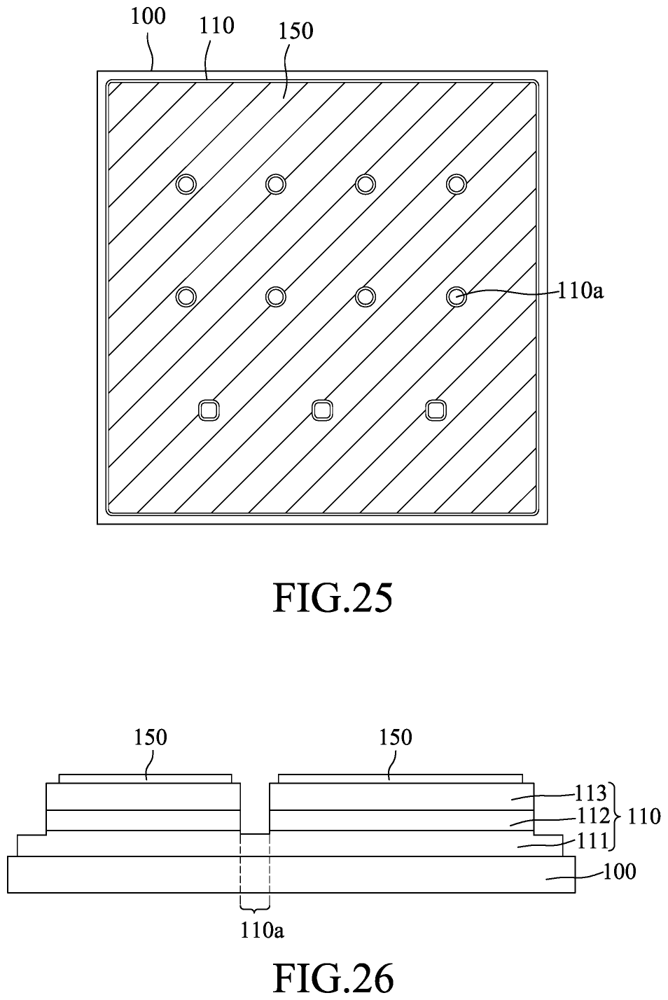

Referring to FIGS. 25 and 26, in certain embodiments, the light-emitting device further includes the transparent conductive layer 150. The transparent conductive layer 150 is formed on the second semiconductor layer 113 by physical vapor deposition or chemical vapor deposition, and is in ohmic contact with the second semiconductor layer 113 for dispersing the externally injected current along the horizontal direction to the top surface of the second semiconductor layer 113 in contact therewith.

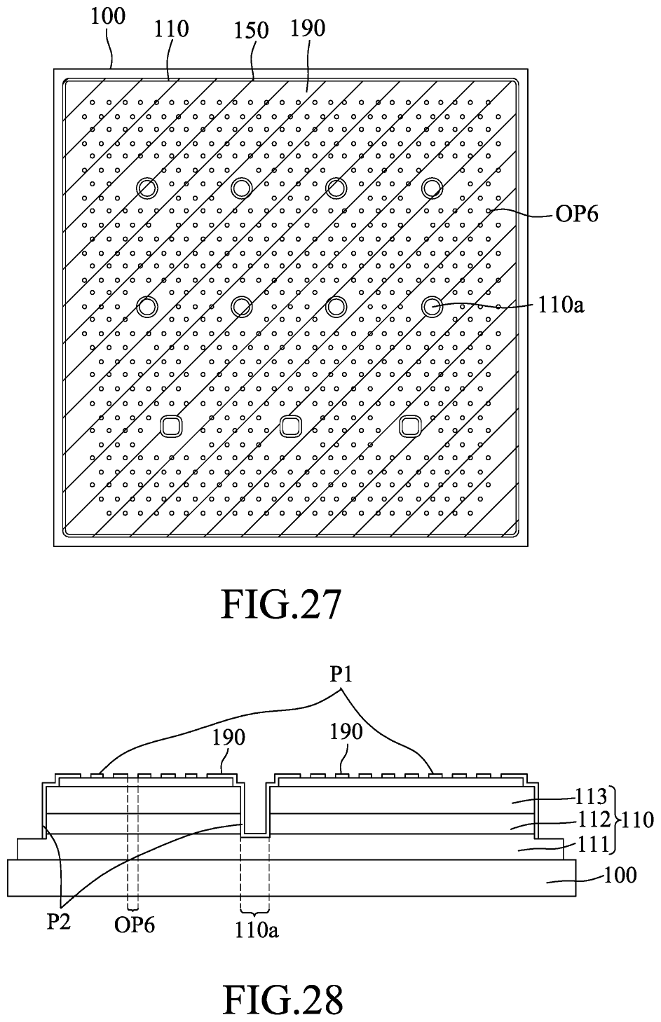

Referring to FIGS. 27 and 28, in one embodiment, the light-emitting device further includes a third insulation layer 190 that is formed on the semiconductor epitaxial structure 110, and that includes a first portion (P1) covering the transparent conductive layer 150 and a second portion (P2) covering the side wall of the semiconductor epitaxial structure 110 and the hole defining walls of the holes 110a. The first portion (P1) and the second portion (P2) are interconnected. The first insulation layer 120 that is subsequently formed is in direct contact with the second portion (P2) at the side wall of the semiconductor epitaxial structure 110 and inside the holes 110a, and is disposed on the second portion (P2). The first portion (P1) is formed with a plurality of discrete sixth grooves (OP6) that expose a portion of the transparent conductive layer 150. A cross section of each of the discrete sixth grooves (OP6) may have a circular or polygonal shape. The discrete sixth grooves (OP6) may be distributed in parallel or intersecting rows and columns.

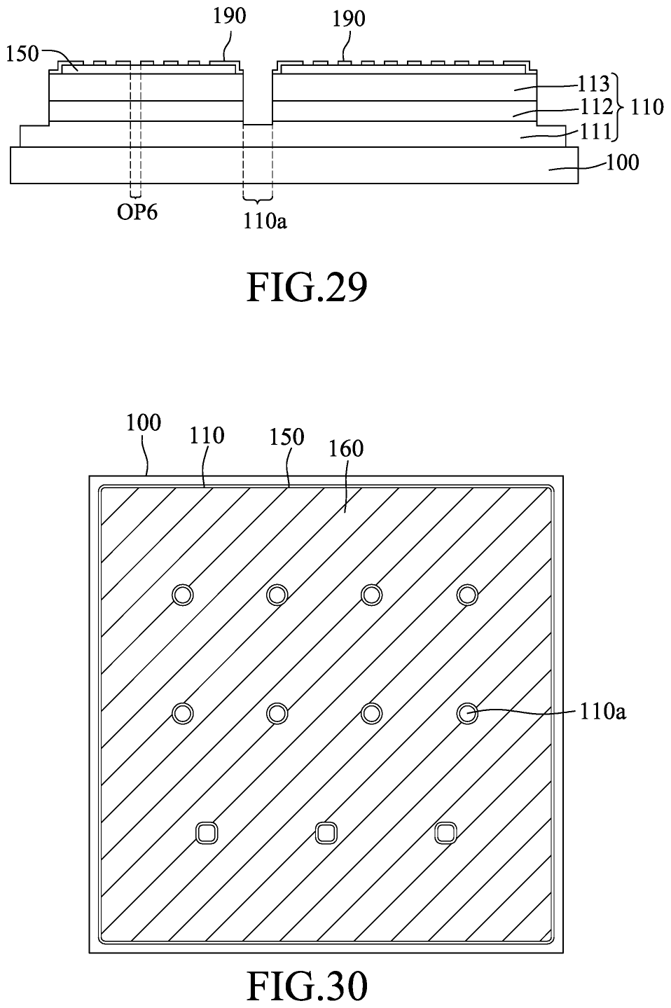

Referring to FIG. 29, in another embodiment, the third insulation layer 190 only covers a top surface and the side wall of the transparent conductive layer 150. Thus, the first insulation layer 120 that is subsequently formed is in direct contact with the side wall of the semiconductor epitaxial structure 110 and the first semiconductor layer 111 exposed from the holes 110a.

In some embodiments, the first portion (P1) of the third insulation layer 190 may be patterned to form the sixth grooves (OP6) by photolithography and etching. The third insulation layer 190 may include a multilayered structure by alternatively stacking dielectric layers having different refractive indices by physical vapor deposition or chemical vapor deposition so as to form a distributed Bragg reflector (DBR). The third insulation layer 190 may be made of SiO₂, SiN, SiOxNy, TiO₂, Si₃N₄, Al₂O₃, TiN, AlN, ZrO₂, TiAlN, TiSiN, HfO, TaO₂, MgF₂, or combinations thereof.

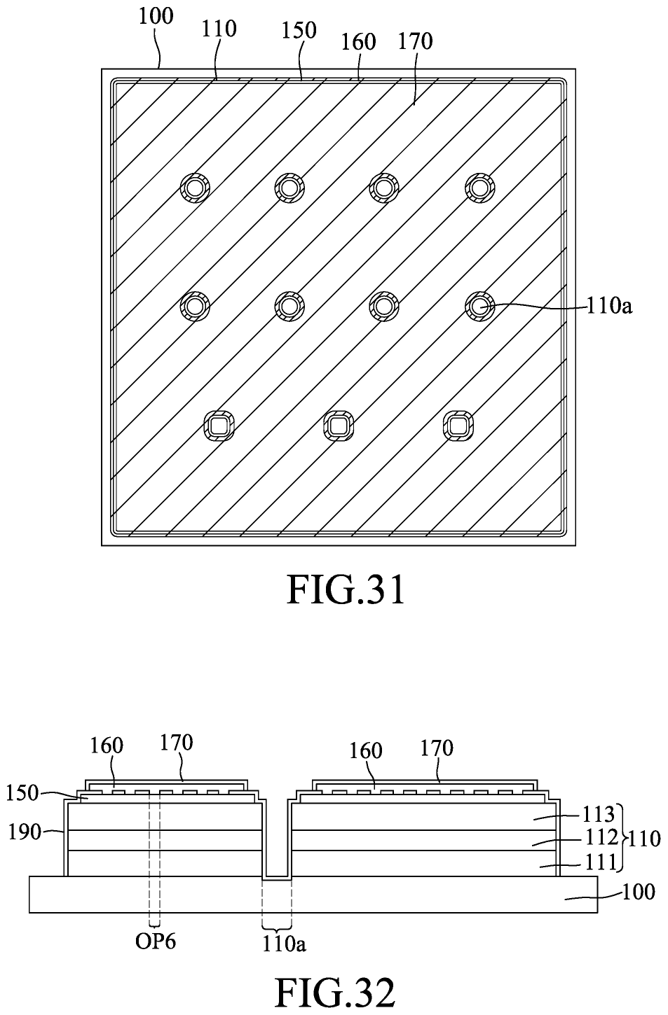

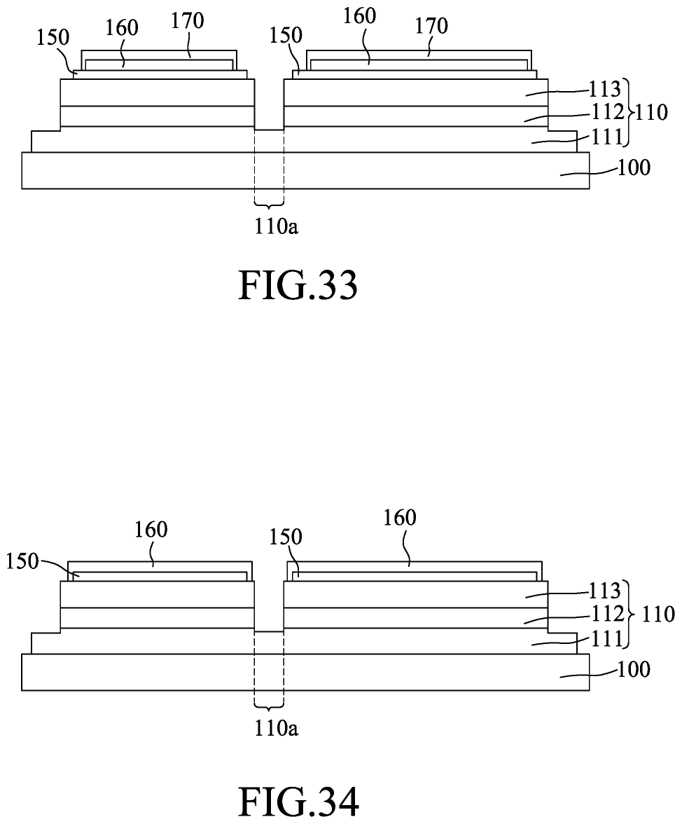

Referring to FIGS. 30 to 32, in certain embodiments, the light-emitting device further includes the metal layer that includes the reflection layer 160 and the barrier layer 170 disposed on the reflection layer 160. The reflection layer 160 is disposed on the third insulation layer 190 to reflect the light, thereby further improving the light extraction efficiency of the light-emitting device. The barrier layer 170 covers the side wall of the reflection layer 160 to prevent the oxidation of the reflection layer 160 as oxidation may cause deterioration of the reflectivity of the reflection layer 160. At the same time, the barrier layer 170 may block metal migration of the reflection layer 160. The side wall of the reflection layer 160 may or may not align with the side wall of the transparent conductive layer 150. The reflection layer 160 forms an electrical contact with the transparent conductive layer 150 through the fifth groove (OP5), so as to diffuse the current to the second semiconductor layer 113 through the transparent conductive layer 150. Alternatively, referring to FIG. 33, in another embodiment, the reflection layer 160 may be directly disposed on the transparent conductive layer 150 and is electrically connected to the transparent conductive layer 150. That is to say, the third insulation layer 190 is no longer formed on the transparent conductive layer 150.

In another embodiment, the step of forming the barrier layer 170 on the reflection layer 160 may be omitted. At the same time, an area of the reflection layer 160 is increased so as to further increase a light reflecting area of the reflection layer 160. For example, referring to FIG. 34, the area of the reflection layer 160 may be greater than an area of the transparent conductive layer 150 such that the transparent conductive layer 150 is covered by the reflection layer 160.

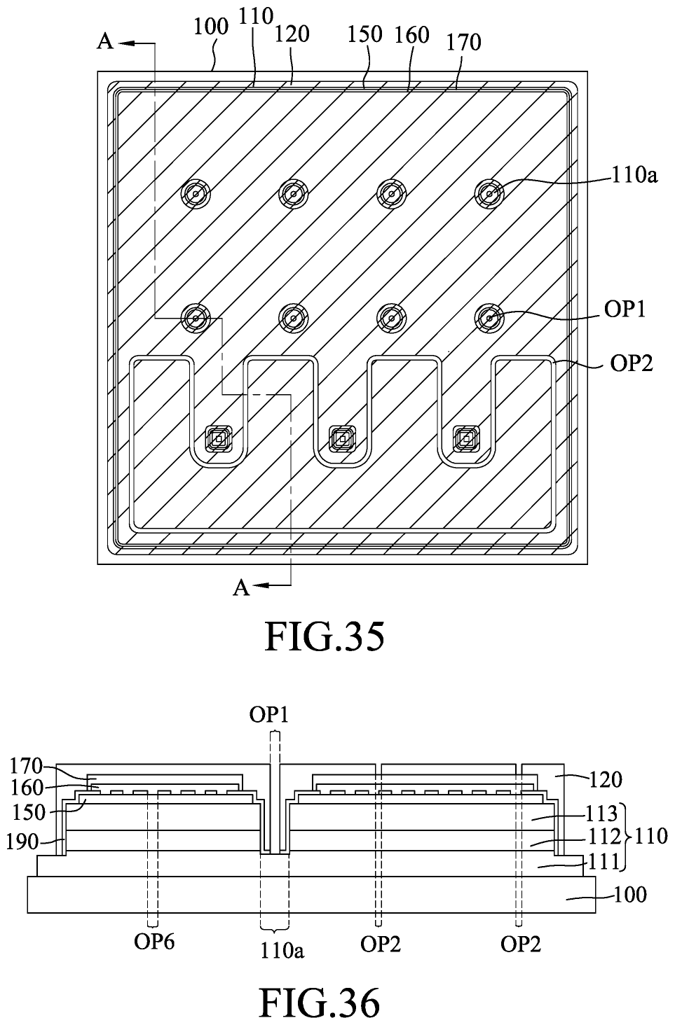

Referring to FIGS. 35 to 36, in certain embodiment, the first insulation layer 120 is formed on the barrier layer 170, and covers the side wall of the semiconductor epitaxial structure 110 and holes 110a. By photolithography and etching, the first insulation layer 120 is patterned to form the first grooves (OP1) and the second groove (OP2).

In some embodiments, the projections of the first grooves (OP1) on the imaginary plane fall within the projections of the holes 110a on the imaginary plane. That is to say, the opening of each of the holes 110a is to be greater than the opening of the respective one of the first grooves (OP1)

The opening of each of the holes 110a is to be greater than the opening of the respective one of the first grooves (OP1), so that the first connection electrode 131 that is subsequently formed may only form an electrical connection with the first semiconductor layer 111 and is electrically isolated from other conductive layers including the second semiconductor layer 113, the transparent conductive layer 150, the reflection layer 160, and the barrier layer 170 due to the presence of the insulation layer 120.

The second groove (OP2) penetrates the first insulation layer 120 to expose the portion of the barrier layer 170, which serves as a path for electrical connection between the subsequently formed second connection electrode 132 and the second semiconductor layer 113. Therefore, a projection of the second groove (OP2) at least partially overlap the projection of the second connection electrode 132. Correspondingly, a cross section of the second groove (OP2) may have a square shape, a circular shape, a ring shape, or other irregular shape. The number of the second grooves (OP2) may be more than one. When the number of the second grooves (OP2) is more than one, the second grooves (OP2) may be distributed symmetrically or in intersecting rows and columns.

Referring to FIGS. 35 to 38, in one embodiment, the second groove (OP2) has an annular shape that divides the first insulation layer 120 into a first insulation portion 121 and a second insulation portion 122, and the first insulation portion 121 surrounds the second insulation portion 122. The first connection electrode 131 is disposed on the first insulation portion 121 and fills the first grooves (OP1) so as to be electrically connected to the first semiconductor layer 111. The second connection electrode 132 is disposed on the second insulation portion 122 and partially fills the second groove (OP2) so as to be electrically connected to the second semiconductor layer 113. The projection of the first connection electrode 131 on the imaginary plane may fall outside a projection of the first insulation portion 121 on the imaginary plane, and a projection of the second insulation portion 122 on the imaginary plane falls within the projection of the second connection electrode 132 on the imaginary plane.

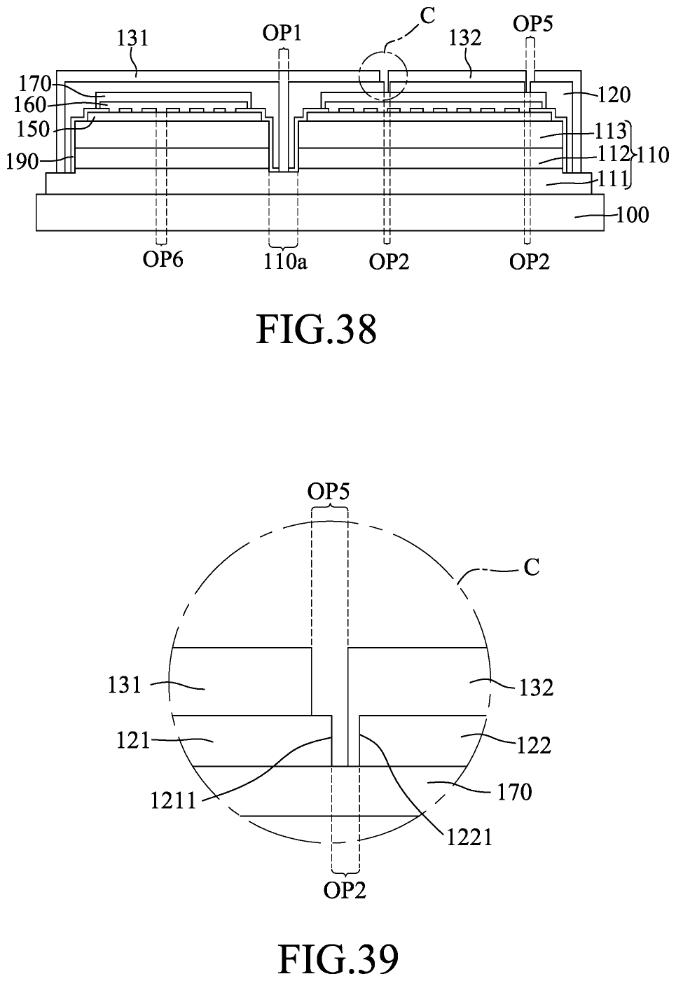

In some embodiments, referring to FIG. 39, which is an enlarged view of the partial region C in FIG. 38, the second groove (OP2) has an outer periphery 1211 proximate to the first insulation portion 121 and an inner periphery 1221 proximate to the second insulation portion 122. A minimum distance between the first connection electrode 131 and the outer periphery 1211 ranges from 1 μm to 15 μm. The second connection electrode 132 covers the inner periphery 1221, and a minimum distance between the second connection electrode 132 and the inner periphery 1221 ranges from 1 μm to 15 μm.

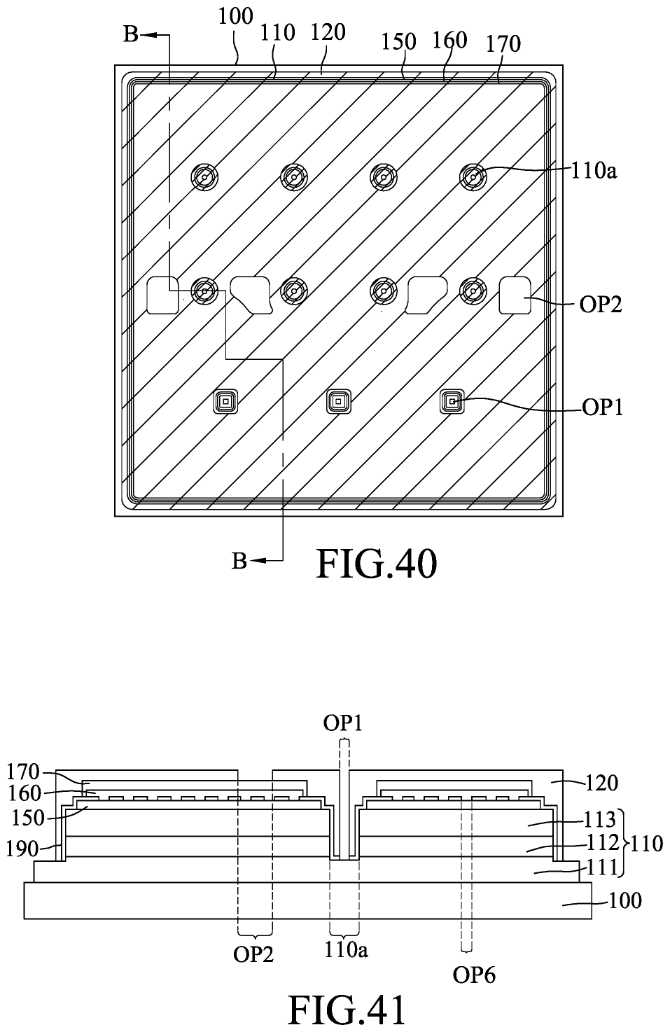

Referring to FIGS. 40 to 43, in another embodiment, the first insulation layer 120 is formed with a plurality of the separated second grooves (OP2) that are irregular in shapes and distributed across a middle section of the first insulation layer 120. The first connection electrode 131 is disposed on the first insulation layer 120 and extends into the first grooves (OP1) to be electrically connected to the first semiconductor layer 111. The second connection electrode 132 is disposed on the first insulation layer 120 and extends into the second grooves (OP2) to be electrically connected to the second semiconductor layer 113. That is to say, the projections of the second grooves (OP2) on the imaginary plane fall within the projection of the second connection electrode 132 on the imaginary plane, so that the second connection electrode 132 completely fills the second grooves (OP2), and that a periphery of the second connection electrode 132 may locate at the top surface the first insulation layer 120.

In some embodiments, the second connection electrode 132 includes the second electrode connection portion 1321 and the plurality of second electrode extension portions 1322 extending from the second electrode connection portion 1321 toward the first connection electrode 131. The projections of the second grooves (OP2) on the imaginary plane fall within the projections of the second electrode extension portions 1322 on the imaginary plane, and the number of the second grooves (OP2) is the same as the number of the second electrode extension portions 1322. Each of the second grooves (OP2) is disposed at a position of the second electrode extension portions 1322 that is proximate to the first connection electrode 131. The closer that the second grooves (OP2) are to the center line (CL) of the light-emitting device, the shorter the transmission path of the current is when the current is injected, thereby reducing current crowding.

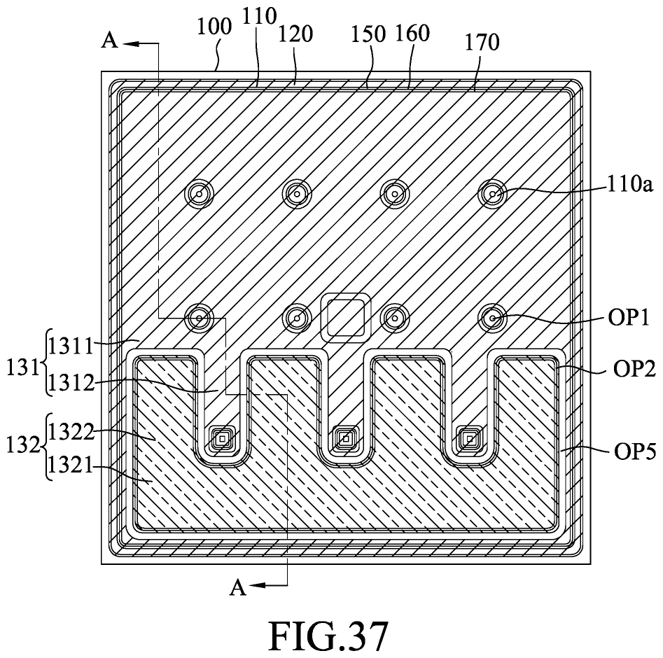

It should be noted that the first connection electrode 131 and the second connection electrode 132 in the aforementioned embodiments are spaced apart from each other by a ring-shaped fifth groove (OP5) that exposes the top surface of the first insulation layer 120, so that the first connection electrode 131 and the second connection electrode 132 are separated from each other. Meanwhile, a minimum width of the fifth groove (OP5) may vary according to arrangement of the second groove(s) (OP2). For example, when the second groove (OP2) has a continuous ring shape in cross section, e.g., as shown in FIGS. 37 and 38, to ensure that the periphery of the second connection electrode 132 falls within the second groove (OP2), and that the first connection electrode 131 is electrically isolated from the second connection electrode 132, the minimum width of the fifth groove (OP5) may be no smaller than 13 μm. When the embodiment has a plurality of discontinuous/discrete second grooves (OP2), the second connection electrode 132 covers and completely fills the second grooves (OP2), and the minimum width of the fifth groove (OP5) may be no smaller than 10 μm, so as to improve a projection area of the second connection electrode 132 on the semiconductor epitaxial structure 110.

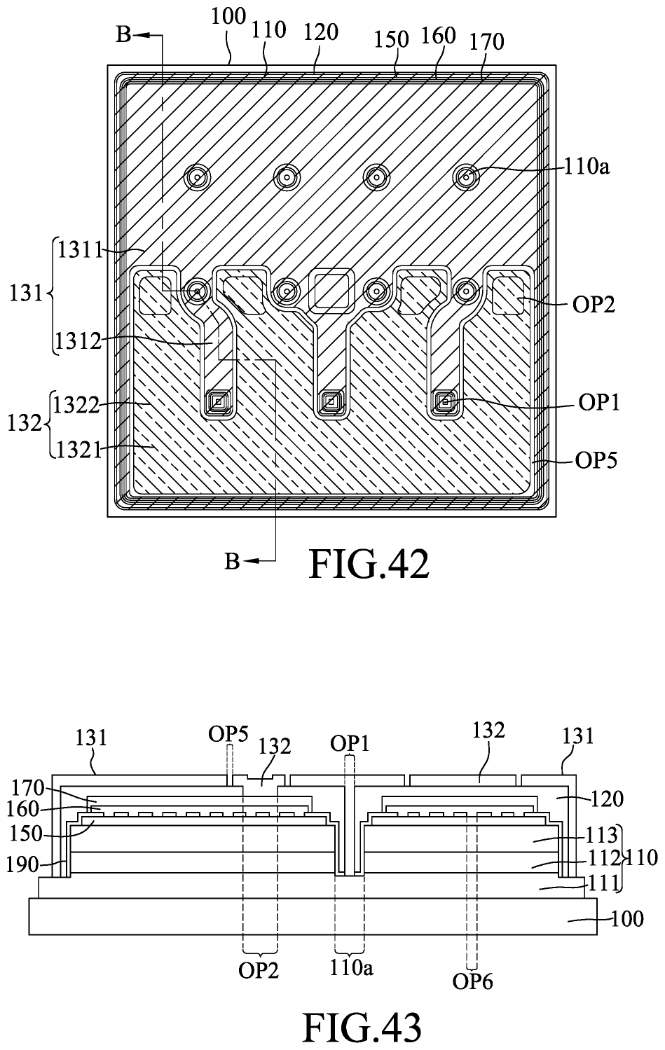

Referring to FIGS. 37 and 42, in one embodiment, the first connection electrode 131 includes the first electrode connection portion 1311 and the plurality of first electrode extension portions 1312 extending from the first electrode connection portion 1311 towards the second connection electrode 132. The first electrode extension portions 1312 and the second electrode extension portions 1322 do not overlap each other, and the width of each of the first electrode extension portions 1312 is smaller than the width of each of the second electrode extension portions 1322, so that the second electrode extension portions 1322 may avoid covering the holes 110a.

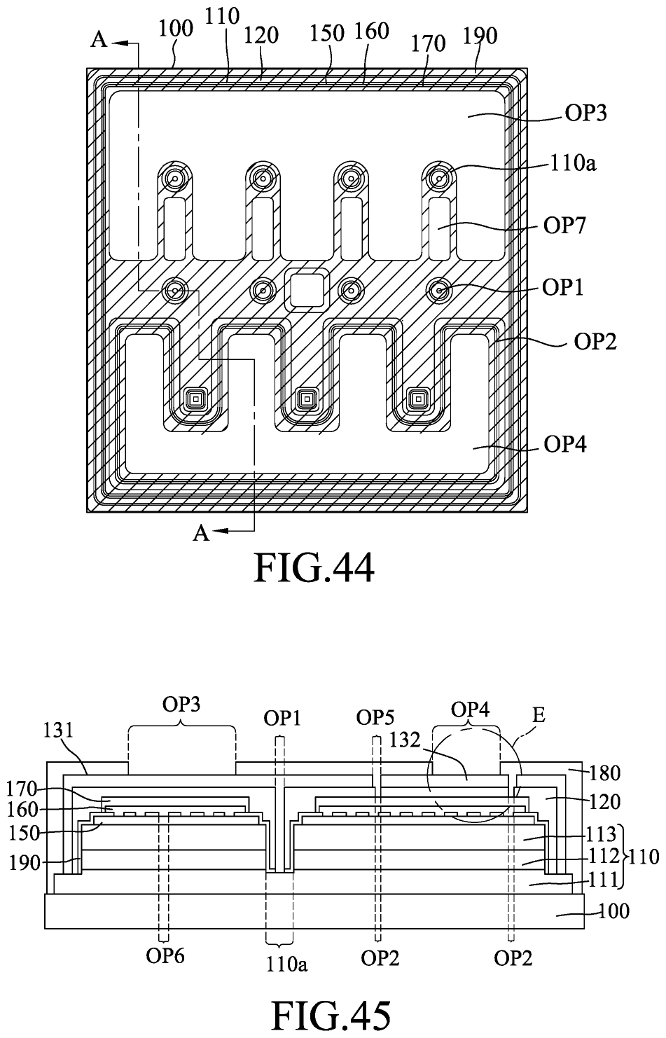

Referring to FIGS. 44 to 47, in certain embodiments, the light-emitting device further includes the second insulation layer 180. The second insulation layer 180 is formed on the first connection electrode 131 and the second connection electrode 132, and is patterned by photolithography and etching to form the third groove (OP3) and the fourth groove (OP4). The third groove (OP3) is formed on the first connection electrode 131 and exposes the portion of the first connection electrode 131. The fourth groove (OP4) is formed on the second connection electrode 132 and exposes the portion of the second connection electrode 132. The third groove (OP3) and the fourth groove (OP4) serve as paths for external electrical connection of the light-emitting device.

In some embodiments, the projection of the third groove (OP3) on the imaginary plane falls within the projection of the first connection electrode 131 on the imaginary plane, and the projection of the fourth groove (OP4) on the imaginary plane falls within the projection of the second connection electrode 132 on the imaginary plane.

In some embodiments, the second insulation layer 180 covers the holes 110a and fills the fifth groove (OP5), thereby further electrically isolating the first connection electrode 131 and the second connection electrode 132 from each other. Meanwhile, the second insulation layer 180 also extends to cover and protect the side wall of the semiconductor epitaxial structure 110 and the first connection electrodes 131 locating on the side wall of the semiconductor epitaxial structure 110.

It should be noted that the projections of the holes 110a on the imaginary plane fall within the projection of the first connection electrode 131 on the imaginary plane. Although the projection of the third groove (OP3) on the imaginary plane also falls within the projection of the first connection electrode 131 on the imaginary plane, the projection of the third groove (OP3) on the imaginary plane does not overlap the projections of the holes 110a on the imaginary plane. That is to say, both of the third groove (OP3) and the fourth groove (OP4) are designed to avoid overlapping the holes 110a.

Referring to FIGS. 44 to 51, in one embodiment, the first pad 141 is disposed in the third groove (OP3), and the second pad 142 is disposed in the fourth groove (OP4). That is to say, the projection of the first pad 141 and the projection of the second pad 142 on the imaginary plane do not overlap the projections of the holes 110a on the imaginary plane, thereby facilitating planarization of the first pad 141 and the second pad 142.

In some embodiments, the projection of the first pad 141 occupies 90% to 100% of the projection of the third groove (OP3) on the imaginary plane, and the projection of the second pad 142 occupies 90% to 100% of the projection of the fourth groove (OP4) on the imaginary plane, thereby further increasing an area of each of the first pad 141 and the second pad 142.

In some embodiments, each of the first pad 141 and the second pad 142 may be a single layered structure or a multilayered structure that may include a metal material having conductivity such as Au, Ti, Ni, Al, Ag, Cr, Pt, etc.

It should be noted that, by increasing the area of each of the first pad 141 and the second pad 142, the bonding area between the packaging substrate and the first pad 141 and the bonding area between the packaging substrate and the second pad 142 in the subsequent packaging process may be increased, thereby improving heat dissipation. By increasing a size of opening of each of the third groove (OP3) and the fourth groove (OP4), the area of each of the first pad 141 and the second pad 142 may be increased, thereby improving heat dissipation of the light-emitting device.

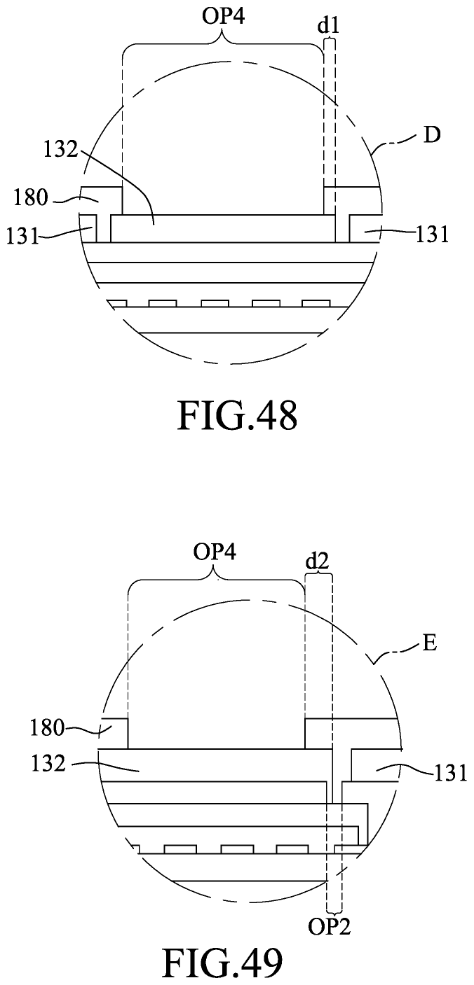

In one embodiment, when the second groove (OP2) with the continuous ring is changed to the design having the plurality of discontinuous/discrete second grooves (OP2), a minimum distance between the fourth groove (OP4) and the second connection electrode 132 may be reduced, thereby increasing an area of the fourth groove (OP4). FIG. 48 is a partial enlarged view of the region D in FIG. 47. Referring to FIG. 48, a minimum distance (X) between the periphery of the second connection electrode 132 proximate to the second grooves (OP2) and a groove-defining wall of the fourth groove (OP4) ranges from 1 μm to 10 μm, so that an area ratio of the fourth groove (OP4) to the second connection electrode 132 may be no smaller than 80%. When the second groove (OP2) has the continuous ring shape, referring to FIG. 49, which is a partial enlarged view of the region E in FIG. 45, since the second connection electrode 132 partially fills the second groove (OP2) to establish the electrical connection with the second semiconductor layer 113, a minimum distance (Y) between the periphery of the second connection electrode 132 and the groove-defining wall of the fourth groove (OP4) is no smaller than 20 μm, thereby making the area ratio of the fourth groove (OP4) to the second connection electrode 132 no greater than 70%. By virtue of the discontinuous second grooves (OP2), the area of the fourth groove (OP4) may be increased, thereby increasing the area of the second pad 142, so that the bonding area between the second pad 142 and an external electrode in the subsequent packaging process may be increased.

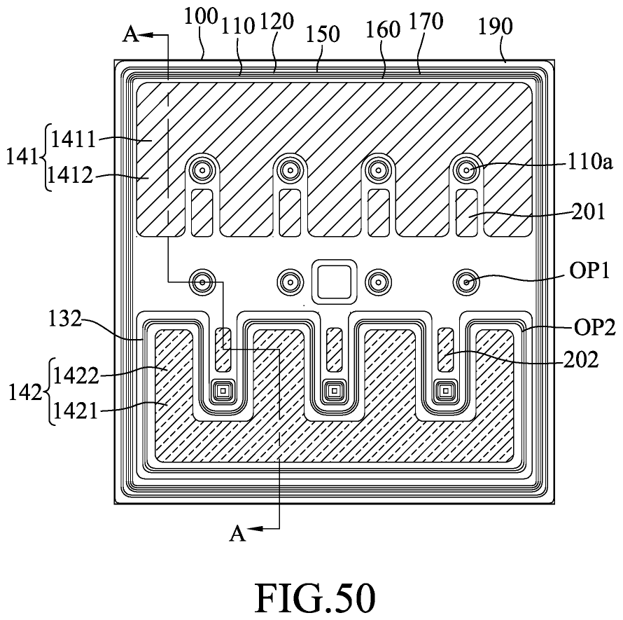

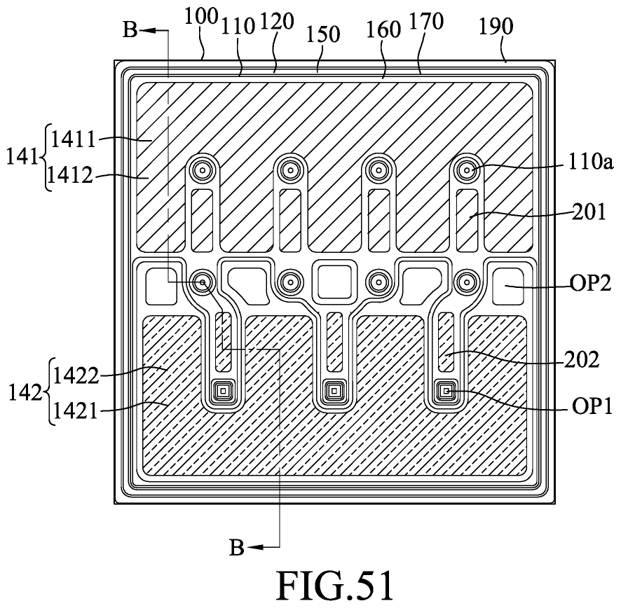

Referring to FIGS. 50 and 51, in one embodiment, the second pad 142 includes the second pad connection portion 1421 and the plurality of second pad extension portions 1422 extending from the second pad connection portion 1421 toward the first pad 141. Moreover, the light-emitting device further includes a plurality of the second electrode blocks 202 each located between corresponding two adjacent second pad extension portions 1422. That is to say, the second electrode blocks 202 are disposed over the second insulation layer 180 that is between the second pad extension portions 1422, and are electrically isolated from the second connection electrode 132. Each of the second electrode blocks 202 has an upper surface that is higher than the upper surface the second pad 142.

Referring to FIG. 51, in one embodiment, the projections of the second grooves (OP2) on the imaginary plane fall outside the projections of the second pad extension portions 1422 on the imaginary plane but inside the projection of the second connection electrode 132 on the imaginary plane. That is to say, the second grooves (OP2) are formed between the first pad 141 and the second pad extension portions 1422, and are proximate to the center line (CL) of the light emitting device, so as to shorten the transmission path when current is injected, thereby reducing current crowding.

In some embodiments, the number of the second grooves (OP2) is the same as the number of the second pad extension portions 1422, and the number of the second electrode blocks 202 is the same as the number of the holes 110a that are proximate to the second pad 142. The projections of the second electrode blocks 202 on the imaginary plane fall inside the projections of the first electrode extension portions 1312 on the imaginary plane.

Referring to FIGS. 50 and 51, in one embodiment, the first pad 141 includes the first pad connection portion 1411 and the plurality of first pad extension portions 1412 extending from the first pad connection portion 1411 toward the second pad 142. The first electrode blocks 201 are located between the first pad extension portions 1412 to further improve heat dissipation capability of the light-emitting device. The projections of the first pad 141, the holes 110a, and the first electrode blocks 201 on the imaginary plane do not overlap each other.

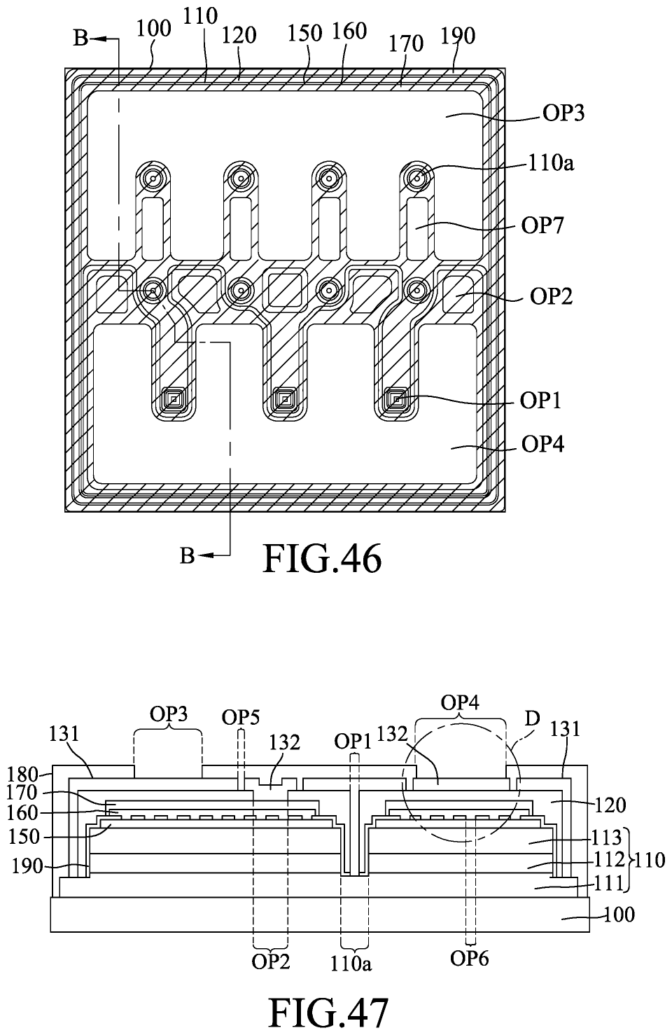

Referring to FIGS. 44 and 46, in some embodiments, before the first electrode blocks 201 are formed, a plurality of seventh grooves (OP7) corresponding in positions and shapes to the first electrode blocks 201 are formed in the second insulation layer 180 by etching. The seventh grooves (OP7) expose a portion of the first connection electrode 131 and are designed to avoid overlapping the holes 110a. In combination with FIGS. 50 and 51, the first electrode blocks 201 are formed in the seventh grooves (OP7), so that the first electrode blocks 201 may be flush with the first pad 141.

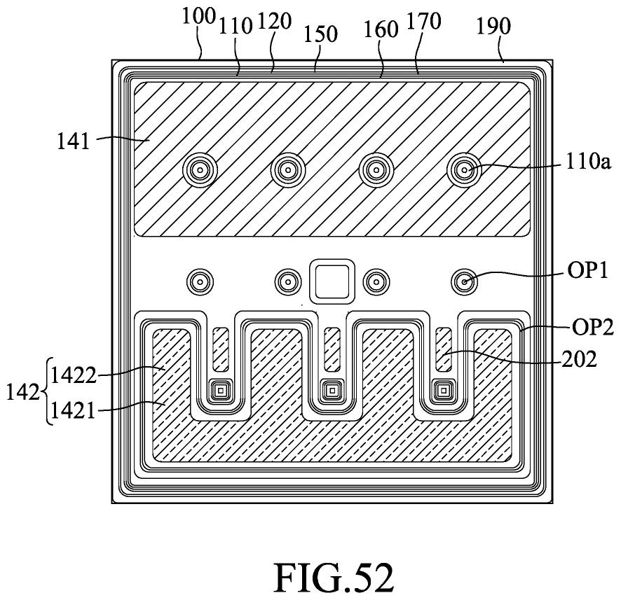

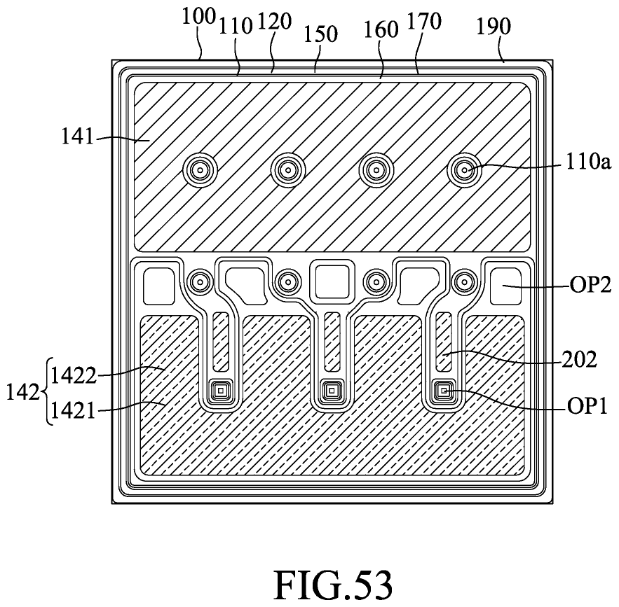

Referring to FIGS. 52 and 53, in another embodiment, the first pad 141 surrounds a peripheral region of some of the holes 110a, so that a region between the first pad extension portions 1412 as shown in, e.g., FIG. 51 may be sufficiently utilized. In this way, the first electrode blocks 201 may be omitted, thereby further increasing the area of the first pad 141. Correspondingly, the third groove (OP3) also surrounds the peripheral region of some of the holes 110a during the etching process, so that the first pad 141 may be formed in the third groove (OP3).

It should be noted that, structures of the first pad 141 and the second pad 142 directly impact the soldering method employed and the soldering yield rate in the subsequent packaging process. For example, referring to FIGS. 50 and 51, in these embodiments, the areas of the first pad 141 and the second pad 142 are substantially equal to each other, so the first pad 141 and the second pad 142 may be soldered by solder paste die attach, reflow soldering using a flux, or hot press soldering attach. Referring to FIGS. 52 and 53, in these embodiments, the area of the first pad 141 is significantly greater than the area of the second pad 142, if solder paste soldering is employed, the amount of solder used in the first pad 141 would be greater than the amount of the solder used in the second pad 142, thereby causing a die to be skewed. Therefore, reflow soldering or hot press soldering is to be employed so that skewing does not occur and that the soldering quality is not adversely affected.

Referring to FIGS. 50 to 53, in some embodiments, while increasing the areas of the first pad 141 and the second pad 142, the minimum distance between the first pad 141 and the second pad 142 may also be kept within a predetermined range for safety reasons, so as to prevent electrodes from short circuiting in the packaging process. In some embodiments, the minimum distance between the first pad 141 and the second pad 142 ranges from 50 μm to 150 μm. In certain embodiments, the minimum distance between the first pad 141 and the second pad 142 is 50 μm, 80 μm, 100 μm, or 150 μm.

The present disclosure provides the light-emitting device that includes the semiconductor epitaxial structure 110, the holes 110a, the first insulation layer 120 disposed on the semiconductor epitaxial structure 110, and the first pad 141, the second pad 142, and the second electrode blocks 202 disposed on the first insulation layer 120. The semiconductor epitaxial structure 110 includes the first semiconductor layer 111, the active layer 112, and the second semiconductor layer 113. The first insulation layer 120 includes the first grooves (OP1) and the second grooves (OP2). The first pad 141 is electrically connected to the first semiconductor layer 111 through the first grooves (OP1), the second pad 142 is electrically connected to the second semiconductor layer 113 through the second grooves (OP2). The second pad 142 includes the second pad connection portion 1421 and the plurality of second pad extension portions 1422 extending from the second pad connection portion 1421 toward the first pad 141. Each of the second electrode blocks 202 is disposed between two adjacent second pad extension portions 1422. The second electrode blocks 202 are used to improve heat dissipation of the light-emitting device and improve the reliability of light-emitting devices.

The light-emitting device includes the second grooves (OP2) disposed on the first insulation layer 120, and the second connection electrode 132 formed on the first insulation layer 120 and filling the second grooves (OP2). The second connection electrode 132 includes the second electrode connection portion 1321 and the second electrode extension portions 1322 extending from the second electrode connection portion 1321 toward the first connection electrode 131. By having the projections of the second grooves (OP2) on the imaginary plane falling within the projections of the second electrode extension portions 1322 on the imaginary plane, and between the projections of the first pad 141 and the second pad 142 on the imaginary plane, the area of the second pad 142 may be further increased, thereby improving heat dissipation of the light-emitting device and the reliability of the light-emitting device.

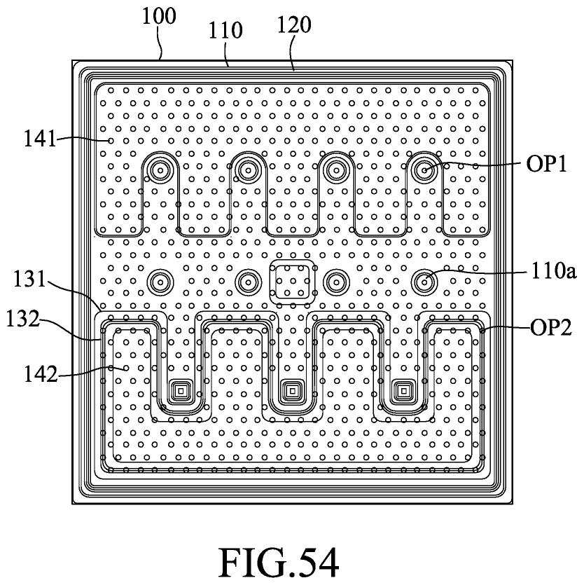

Referring to FIG. 54, which is a schematic diagram of a conventional light-emitting device. The second groove (OP2) has the continuous ring shape and surrounds the second pad 142 and separates the first connection electrode 131 from the second connection electrode 132 electrically. To avoid short circuiting between different electrodes, the second pad 142 is to be enclosed by the second groove (OP2), and to be separated from the second groove (OP2) by a predetermined distance. By such configuration, the area of the second pad 142 is limited. It is known by those skilled in the art that the area of the second pad 142 directly impacts thermal diffusivity of the light-emitting device and reliability of the subsequent packaging process. That is to say, the second pad 142 having a greater area may further improve the reliability of the light-emitting device.

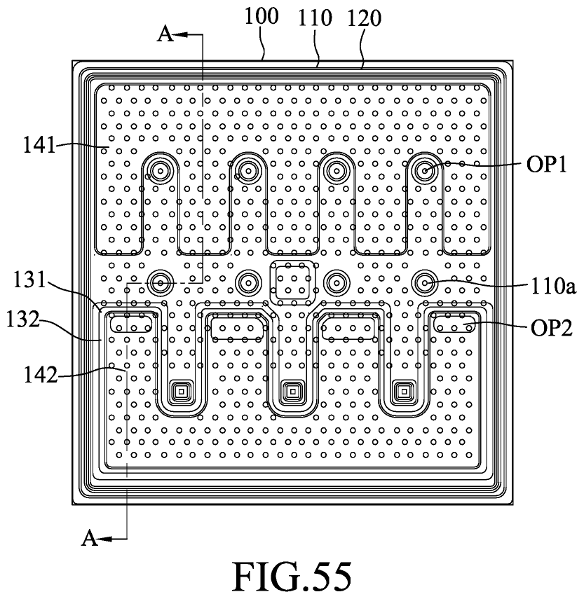

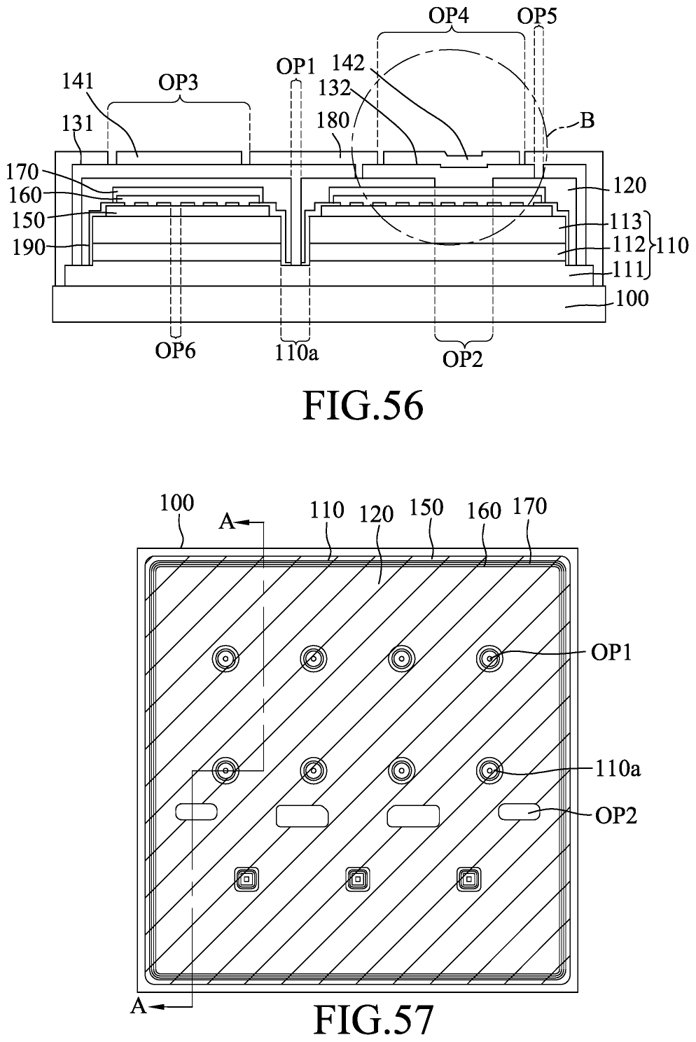

According to the above analysis, the present disclosure provides an embodiment of a light-emitting device that may increase the area of the second pad 142, thereby improving the reliability of the light-emitting device. Referring to FIGS. 55 and 56, where FIG. 55 is a schematic top view of the light-emitting device according to the embodiment of the present disclosure, and FIG. 56 is a schematic cross-sectional view taken along line A-A of FIG. 55.

The light-emitting device includes the substrate 100, the semiconductor epitaxial structure 110 disposed on the substrate 100 and having the plurality of holes 110a, the first insulation layer 120 disposed on the semiconductor epitaxial structure 110, and the first pad 141 and the second pad 142 disposed on the first insulation layer 120.

The semiconductor epitaxial structure 110 includes the first semiconductor layer 111, the active layer 112, and the second semiconductor layer 113 sequentially stacked on the substrate 100 in such order in the laminating direction. The holes 110a are respectively defined by the hole-defining walls and extend downward from the predetermined locations of the top surface of the second semiconductor layer 113 through the second semiconductor layer 113 and the active layer 112 to expose the portion of the first semiconductor layer 111.

The first insulation layer 120 is disposed on and covers the top surface of the semiconductor epitaxial structure 110, the side wall (in the step form in this embodiment) of the semiconductor epitaxial structure 110, and the part of the surface of the substrate 100 proximate to the semiconductor epitaxial structure 110. The first insulation layer 120 is also formed on the hole-defining walls. The first insulation layer 120 has the plurality of first grooves (OP1) and the plurality of second grooves (OP2). Each of the first grooves (OP1) is located in the center portion of the respective one of the holes 110a and exposes the portion of the first semiconductor layer 111 exposed from the holes 110a.

The first pad 141 and the second pad 142 are formed on the semiconductor epitaxial structure 110. The first pad 141 is electrically connected to the first semiconductor layer 111 through the first grooves (OP1). The second pad 142 is electrically connected to the second semiconductor layer 113 through the second groove (OP2). The projection of the first pad 141 on the imaginary plane does not overlap the projections of the holes 110a on the imaginary plane, and the projections of the second grooves (OP2) on the imaginary plane fall within the projection of the second pad 142 on the imaginary plane.

By virtue of the projections of the second grooves (OP2) on the imaginary plane falling within the projection of the second pad 142 on the imaginary plane, the second pad 142 may directly cover the second grooves (OP2), and thereby being electrically connected to the second semiconductor layer 113. In other words, the second pad 142 is no longer limited by the second grooves (OP2) as shown in the conventional light-emitting device (see FIG. 54), so the area of the second pad 142 may further be increased, thereby improving heat dissipation of the light-emitting device and the reliability of the subsequent packaging process.

It should be noted that the number and manner of distribution of the holes 110a on the semiconductor epitaxial structure 110 may vary according to the size of the light-emitting device. When the size of the light-emitting device is greater, the number of the holes 110a is greater so as to ensure the voltage requirement. For example, in this embodiment, the holes 110a proximate to the first pad 141 and the holes 110a proximate to the second pad 142 are arranged in asymmetrically relative to the center line (CL).

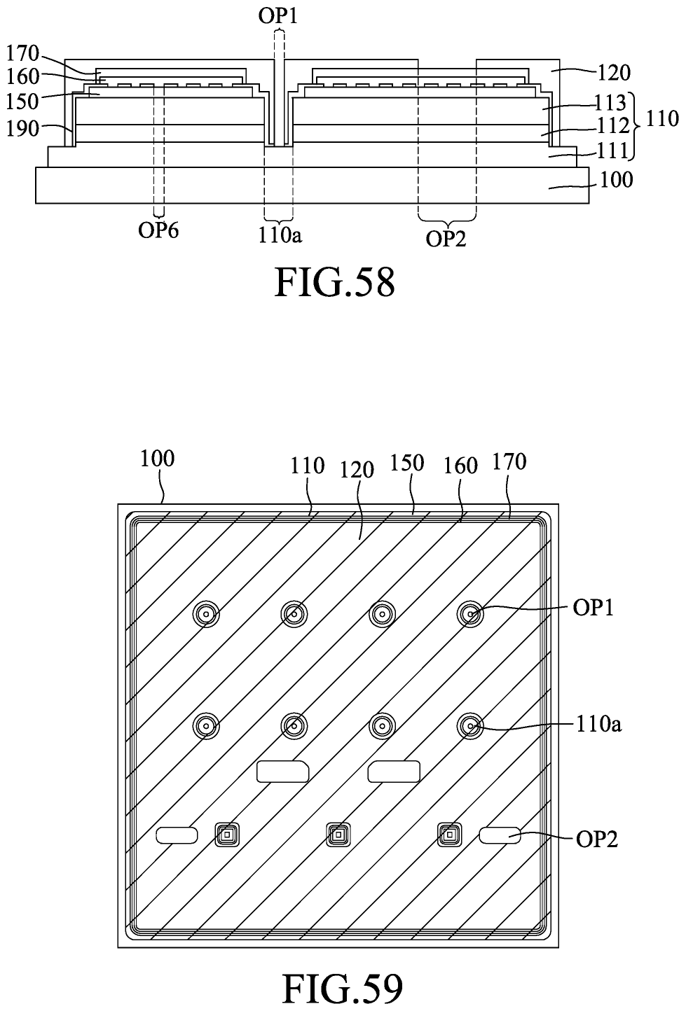

Referring to FIGS. 57 and 58, in certain embodiments, the first insulation layer 120 is formed on the barrier layer 170, and covers the side wall of the semiconductor epitaxial structure 110 and holes 110a. By photolithography and etching, the first insulation layer 120 is patterned to form the first grooves (OP1) and the second grooves (OP2).

The number of the first grooves (OP1) is the same as the number of the holes 110a. The first grooves (OP1) penetrate the first insulation layer 120 and the third insulation layer 190 to expose the portion of the first semiconductor layer 111 which allows the first connection electrode 131 being formed therein and being electrically connected to the first semiconductor layer 111.

In some embodiments, the projection of each the first grooves (OP1) on the imaginary plane falls within the projection of the respective one of the holes 110a on the imaginary plane. That is to say, the opening of each of the holes 110a is to be greater than the opening of the respective one of the first grooves (OP1), so that the first connection electrode 131 that is subsequently formed may only form an electrical connection with the first semiconductor layer 111 and is electrically isolated from other conductive layers including the second semiconductor layer 113, the transparent conductive layer 150, the reflection layer 160, and the barrier layer 170 due to the presence of the insulation layer 120.

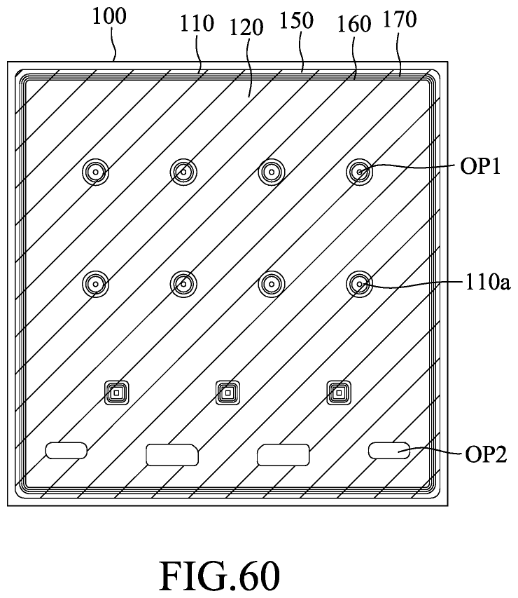

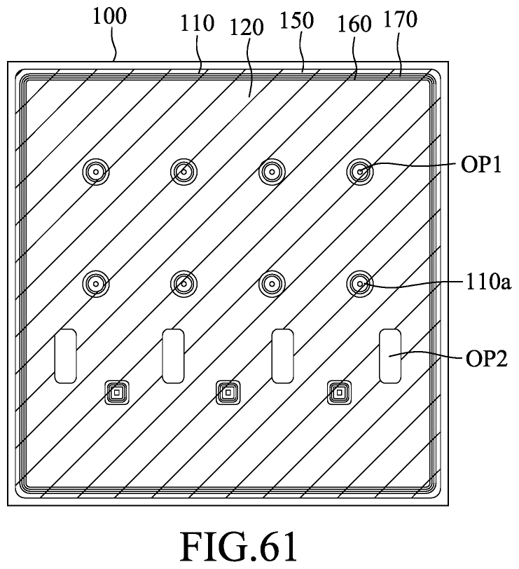

The second grooves (OP2) serve as paths for electrical connection between the subsequently formed second connection electrode 132 and the second semiconductor layer 113. Therefore, the projections of the second grooves (OP2) on the imaginary plane are to fall within the projection the second connection electrode 132 on the imaginary plane. The cross section of each of the second groove (OP2) may have a square shape, a circular shape, a ring shape, or other irregular shape. The number of the second groove (OP2) may be more than one. When the number of the second grooves (OP2) is more than one, the second grooves (OP2) may be distributed symmetrically or in intersecting rows and columns. FIGS. 59 to 61 show different arrangements of the second grooves (OP2). The shapes, positions, and number of the second grooves (OP2) in this disclosure are not limited thereto.

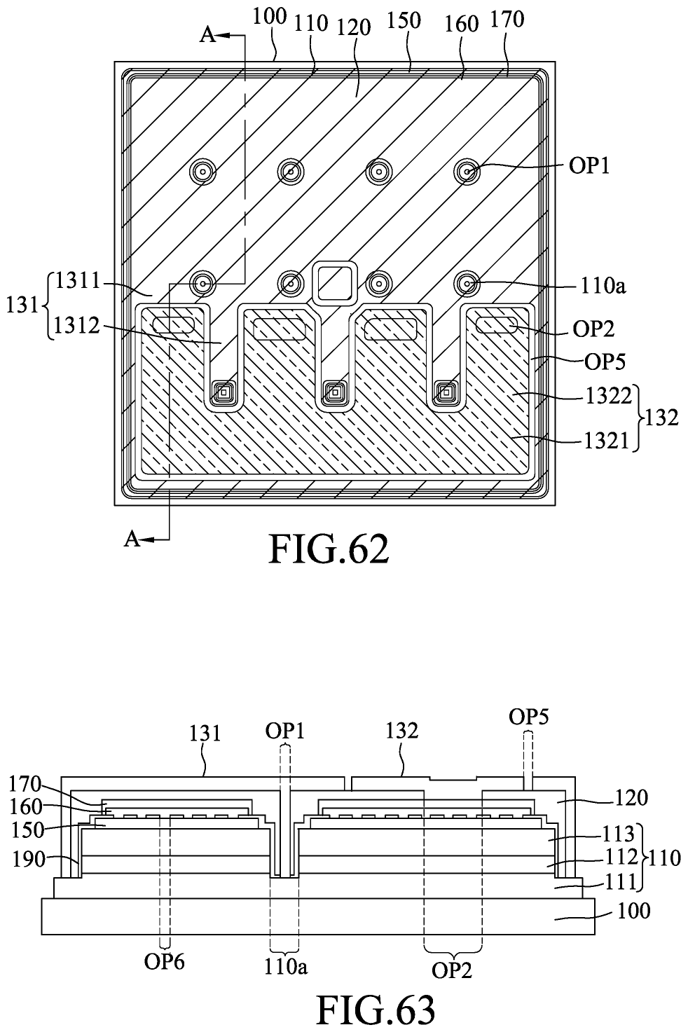

Referring to FIGS. 62 and 63, in one embodiment, the first connection electrode 131 is disposed on the first insulation layer 120 and fills the first grooves (OP1) so as to be electrically connected to the first semiconductor layer 111. The second connection electrode 132 is disposed on the first insulation layer 120 and fills the second grooves (OP2) so as to be electrically connected to the second semiconductor layer 113. Moreover, the first connection electrode 131 and the second connection electrode 132 are spaced apart from each other by the ring-shaped fifth groove (OP5) that exposes the top surface of the first insulation layer 120, so that the first connection electrode 131 and the second connection electrode 132 are separated from each other.

In some embodiments, the first connection electrode 131 includes the first electrode connection portion 1311 and the plurality of first electrode extension portions 1312 extending from the first electrode connection portion 1311 towards the second connection electrode 132, and the second connection electrode 132 includes the second electrode connection portion 1321 and the plurality of second electrode extension portions 1322 extending from the second electrode connection portion 1321 towards the first connection electrode 131.

The projections of the second grooves (OP2) on the imaginary plane fall within the projections of the second electrode extension portions 1322 on the imaginary plane, so that the second connection electrode 132 may completely fill the second grooves (OP2) to be electrically connected to the second semiconductor layer 113.

In some embodiments, the first electrode extension portion 1312 does not overlap the second electrode extension portion 1322, and the width of each of the first electrode extension portions 1312 is smaller than the width of each of the second electrode extension portions 1322, so that the second electrode extension portions 1322 may avoid covering the holes 110a.

In some embodiments, each of the first connection electrode 131 and the second connection electrode 132 may be a single layered structure or a multilayered structure that includes a metal material having conductivity such as Au, Ti, Ni, Al, Ag, Gr, Pt or the like, or any alloy thereof. The minimum distance between the first connection electrode 131 and the second connection electrode 132 is no smaller than 1 μm. That is to say, a minimum width of the sixth groove (OP6) is no smaller than 1 μm.

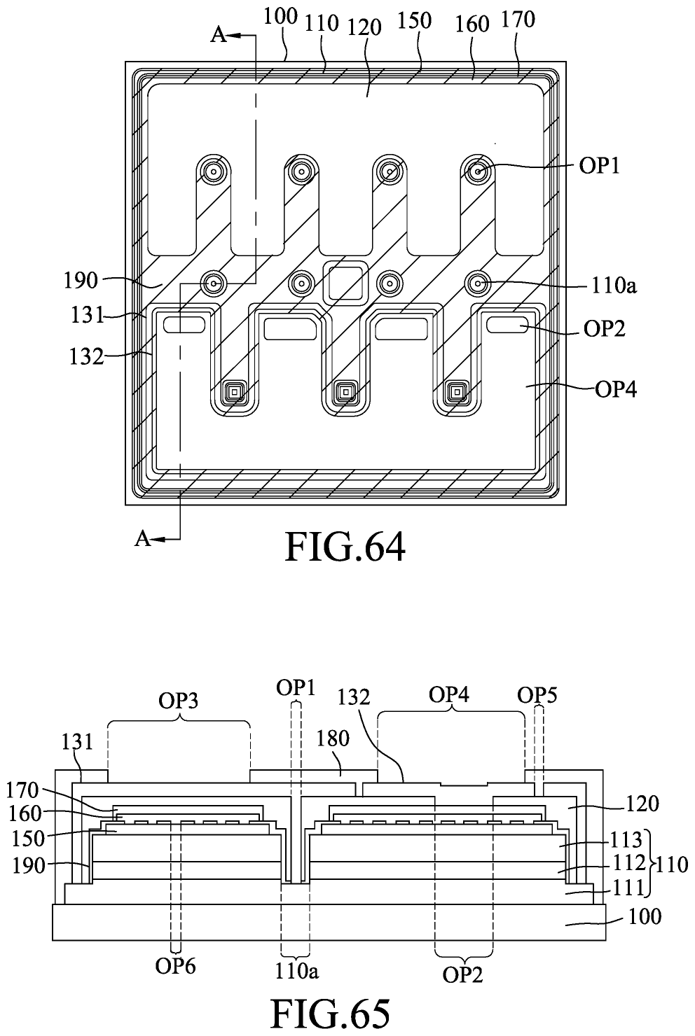

Referring to FIGS. 64 and 65, in certain embodiments, the light-emitting device further includes the second insulation layer 180. The second insulation layer 180 is formed on the first connection electrode 131 and the second connection electrode 132. By photolithography and etching, the second insulation layer 180 is patterned to form the third groove (OP3) and the fourth groove (OP4). The third groove (OP3) is formed on the first connection electrode 131 and exposes the portion of the first connection electrode 131. The fourth groove (OP4) is formed on the second connection electrode 132 and exposes the portion of the second connection electrode 132. The third groove (OP3) and the fourth groove (OP4) serve as paths for external electrical connection of the light-emitting device.

In some embodiments, the projection of the third groove (OP3) on the imaginary plane falls within the projection of the first connection electrode 131 on the imaginary plane, and the projection of the fourth groove (OP4) on the imaginary plane falls within the projection of the second connection electrode 132 on the imaginary plane.

In some embodiments, the second insulation layer 180 covers the holes 110a and fills the fifth groove (OP5), thereby further electrically isolating the first connection electrode 131 and the second connection electrode 132 from each other. Meanwhile, the second insulation layer 180 also extends to cover the side wall of the semiconductor epitaxial structure 110, so as to form the protection on the first connection electrodes 131 that covers the side wall of the semiconductor epitaxial structure 110.

It should be noted that the first connection electrode 131 is disposed on the second insulation layer 180 and fills the first grooves (OP1) so as to be electrically connected to the first semiconductor layer 111. In other words, the projections of the holes 110a on the imaginary plane fall within the projection of the first connection electrode 131 on the imaginary plane. Despite the projection of the third groove (OP3) on the imaginary plane falling within the projection of the first connection electrode 131 on the imaginary plane, the projection of the third groove (OP3) on the imaginary plane does not overlap the projections of the holes 110a on the imaginary plane. A minimum distance between a periphery of the second pad 142 and a periphery of the second connection electrode 132 ranges from 6 μm to 12 μm.

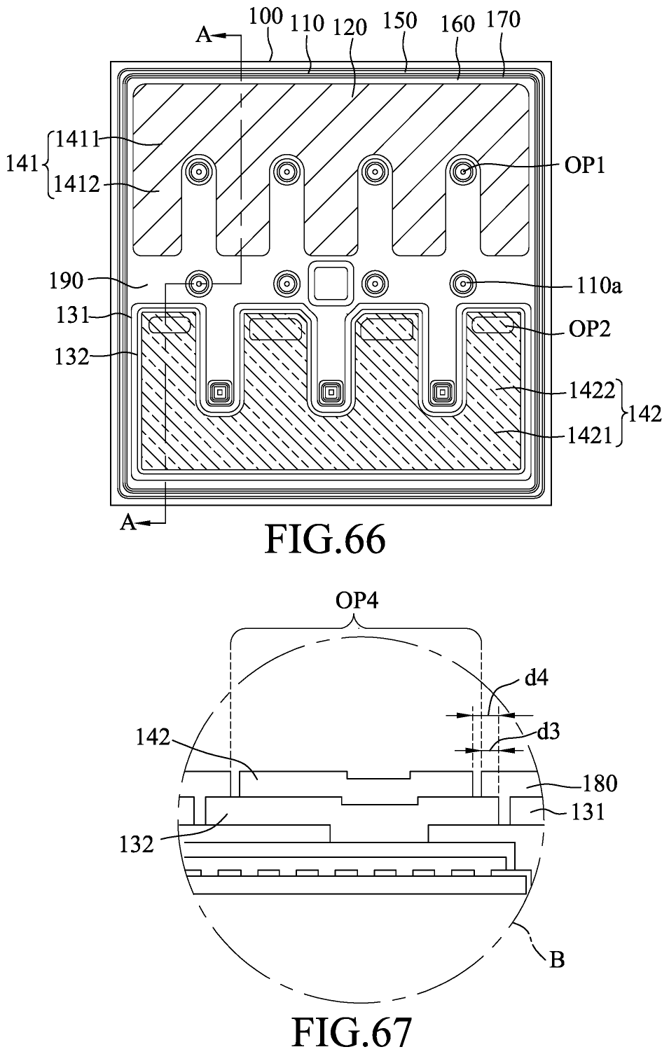

Referring to FIGS. 56 and 66, in certain embodiments, the first pad 141 is disposed in the third groove (OP3), and the second pad 142 is disposed in the fourth groove (OP4). That is to say, the projection of the first pad 141 and the projection of the second pad 142 on the imaginary plane do not overlap the projections of the holes 110a on the imaginary plane, thereby facilitating planarization of the first pad 141 and the second pad 142.

In some embodiments, the projection of the first pad 141 occupies 90% to 100% of the projection of the third groove (OP3) on the imaginary plane, and the projection of the second pad 142 occupies 90% to 100% of the projection of the fourth groove (OP4) on the imaginary plane, thereby further increasing the area of each of the first pad 141 and the second pad 142.

In some embodiments, each of the first pad 141 and the second pad 142 may be a single layered structure or a multilayered structure that may include a metal material having conductivity such as Au, Ti, Ni, Al, Ag, Gr, Pt, etc.

It should be noted that, by increasing the area of each of the first pad 141 and the second pad 142, the bonding area between the packaging substrate and the first pad 141 and the bonding area between the packaging substrate and the second pad 142 in the subsequent packaging process may be increased, thereby improving heat dissipation. By increasing the size of the opening of each of the third groove (OP3) and the fourth groove (OP4), the area of each of the first pad 141 and the second pad 142 may be increased, thereby improving heat dissipation of the light-emitting device.

Referring to FIGS. 56 and 66, in certain embodiments, the projections of the second grooves (OP2) on the imaginary plane fall within the projection of the second pad 142 on the imaginary plane, thereby reducing the minimum distance between the fourth groove (OP4) and the second connection electrode 132, and increasing the area of the fourth groove (OP4). In this embodiment, referring to FIG. 67, which is a partial enlarged view of region B in FIG. 56, a minimum distance (d3) between the periphery of the second connection electrode 132 and the groove-defining wall of the fourth groove (OP4) ranges from 4 μm to 10 μm, and a minimum distance (d4) between the periphery of the second connection electrode 132 and a periphery of the second pad 142 ranges from 6 μm and 12 μm, so that the area ratio of the fourth groove (OP4) to the second connection electrode 132 may be no smaller than 85%. In the conventional light-emitting device as shown in FIG. 54, since the second connection electrode 132 partially fills the second grooves (OP2) so as to be electrically connected to the second semiconductor layer 113, thereby keeping the minimum distance between the fourth groove (OP4) and the second connection electrode 132 no greater than 20 μm, so that the second insulation layer 180 may partially fill the second grooves (OP2). In this way, short circuit caused by water invasion due to an exposed side wall of the second connection electrode 132 may be avoided; however, the area ratio of the fourth groove (OP4) to the second connection electrode 132 is kept to be no greater than 70%. In other words, the present disclosure may increase the area of the fourth groove (OP4), thereby increasing the area of the second pad 142 and the bonding area between the second pad 142 and an external electrode in the subsequent packaging process.

It should be noted that, referring to FIG. 56 and FIG. 66, since the projections of the second grooves (OP2) on the imaginary plane fall within the projection of the second pad 142 on the imaginary plane, the second pad 142 may have recesses formed over the second grooves (OP2). However, the second grooves (OP2) are formed in the first insulation layer 120, and by reducing a thickness of the first insulation layer 120 formed on the barrier layer 170, depth of the second grooves (OP2) may be reduced, thereby reducing depth of the recesses of the second pad 142 formed over the second grooves (OP2). The smaller the depth of the recesses of the second pad 142 is, the smaller the porosity between the second pad 142 and the external electrode in the subsequent packaging process.

In some embodiments, the second pad 142 includes the second pad connection portion 1421 and the plurality of second pad extension portions 1422 extending from the second pad connection portion 1421 toward the first pads 141. The projections of the second grooves (OP2) on the imaginary plane may fall within the projections of the second pad extension portions 1422 on the imaginary plane, within a projection of the second pad connection portion 1421 on the imaginary plane, or within the projections of the second pad extension portions 1422 and the projection of the second pad connection portion 1421 on the imaginary plane at the same time (may also refer to FIGS. 59 to 61).

In some embodiments, the projections of the second grooves (OP2) on the imaginary plane fall within the projections of the second pad extension portions 1422 on the imaginary plane, and the number of the second grooves (OP2) is the same as the number of the second pad extension portions 1422. The second grooves (OP2) are formed in the second pad extension portions 1422 that are proximate to the first pad 141, thereby effectively shortening the transmission path of the current when the current is injected, and reducing current crowding.

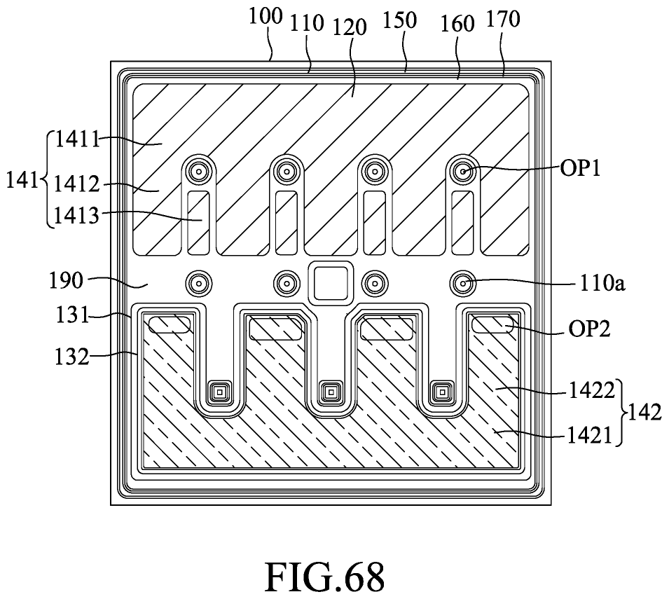

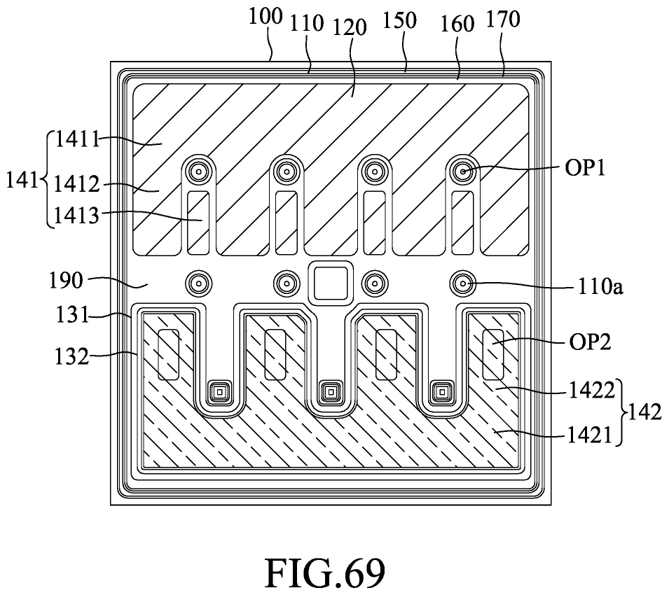

Referring to FIGS. 68 and 69, in one embodiment, the first pad 141 includes the first pad connection portion 1411, the plurality of first pad extension portions 1412 extending from the first pad connection portion 1411 toward the second pad 142, and a plurality of third electrode blocks 1413 extending toward the second pad 142. The third electrode blocks 1413 are formed synchronously with the first pad connection portion 1411 and the first pad extension portions 1412. The projections of the first pad extension portions 1412 on the imaginary plane do not overlap the projections of the holes 110a on the imaginary plane. By such configuration, heat dissipation of the light-emitting device is improved.

In some embodiments, before the third electrode blocks 1413 are formed, grooves corresponding to the third electrode blocks 1413 in shape are formed in the second insulation layer 180 by etching, which exposes portions of the first connection electrode 131 and which is not register with the holes 110a. The third electrode blocks 1413 are formed in such grooves, so as to planarize the upper surface of the first pad 141.

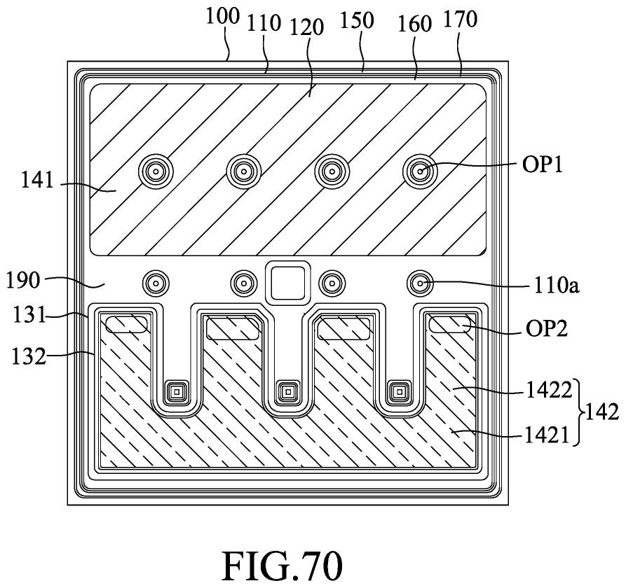

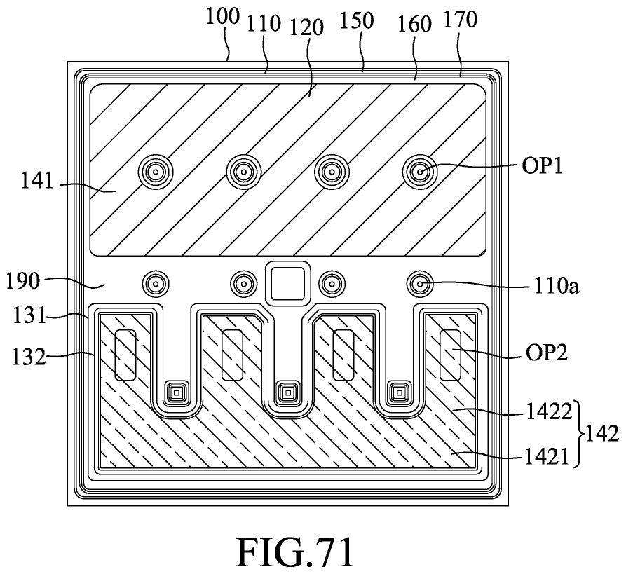

Referring to FIGS. 70 and 71, in another embodiment, the first pad 141 surrounds a peripheral region of some of the holes 110a, so that the region between the first pad extension portions 1412 may be sufficiently utilized and the area of the first pad 141 is increased. Correspondingly, the third groove (OP3) also surrounds the peripheral region of some of the holes 110a during the etching process, so that the first pad 141 may be formed in the third groove (OP3).

It should be noted that, the structures of the first pad 141 and the second pad 142 directly impact the soldering method employed and the soldering yield rate in the subsequent packaging process. For example, referring to FIGS. 68 and 69, in these embodiments, the areas of the first pad 141 and the second pad 142 are substantially equal to each other, so the first pad 141 and the second pad 142 may be soldered by solder paste die attach, reflow soldering using a flux, or hot press soldering attach. Referring to FIGS. 70 and 71, in these embodiments, the area of the first pad 141 is significantly greater than the area of the second pad 142, if solder paste soldering is employed, the amount of solder used in the first pad 141 would be greater than the amount of the solder used in the second pad 142, thereby causing a die to be skewed. Therefore, reflow soldering or hot press soldering is to be employed so that skewing does not occur and that the soldering quality is not adversely affected.

In some embodiments, while increasing the areas of the first pad 141 and the second pad 142, the minimum distance between the first pad 141 and the second pad 142 may also be kept within a predetermined range for safety reasons, so as to prevent electrodes from short circuiting in the packaging process. In some embodiments, the minimum distance between the first pad 141 and the second pad 142 ranges from 50 μm to 150 μm. In certain embodiments, the minimum distance between the first pad 141 and the second pad 142 is 50 μm, 80 μm, 100 μm, or 150 μm.

The present disclosure provides the light-emitting device that includes the semiconductor epitaxial structure 110, the holes 110a, the first insulation layer 120 disposed on the semiconductor epitaxial structure 110, and the first pad 141 and the second pad 142 disposed on the first insulation layer 120. The semiconductor epitaxial structure 110 includes the first semiconductor layer 111, the active layer 112, and the second semiconductor layer 113. The first insulation layer 120 includes the first grooves (OP1) and the second grooves (OP2). The first pad 141 is electrically connected to the first semiconductor layer 111 through the first grooves (OP1), and the second pad 142 is electrically connected to the second semiconductor layer 113 through the second grooves (OP2). By having the projections of the second grooves (OP2) on the imaginary plane falling within the projection of the second pad 142 on the imaginary plane, the injection area of current of the second pad 142 may be increased, heat dissipation of the light-emitting device may be improved, thereby improving the reliability of the light-emitting device.

In addition to the aforementioned embodiments, the light-emitting device provided by the present disclosure may also be applied to fields including, but not limited to, indoor lighting, vehicles, etc. In particular, in the field of vehicle lighting where reliability requirements for the light-emitting device is higher.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting device, comprising:
a semiconductor epitaxial structure that includes a first semiconductor layer, an active layer, and a second semiconductor layer sequentially stacked in such order in a laminating direction, and that has a plurality of holes penetrating said second semiconductor layer and said active layer and exposing a portion of said first semiconductor layer;
a first insulation layer that is disposed on said semiconductor epitaxial structure, and that has a plurality of first grooves and a plurality of second grooves, said first grooves exposing said portion of said first semiconductor layer;
a first pad that is formed on said semiconductor epitaxial structure and that is electrically connected to said first semiconductor layer through said first grooves, a projection of said first pad on an imaginary plane perpendicular to said laminating direction not overlapping projections of said holes on said imaginary plane; and
a second pad that is formed on said semiconductor epitaxial structure and that is electrically connected to said second semiconductor layer through said second grooves, a projection of said second pad on said imaginary plane not overlapping said projections of said holes on said imaginary plane;
wherein said first pad includes a first pad connection portion and a plurality of first pad extension portions extending from said first pad connection portion toward said second pad, and said second pad includes a second pad connection portion and a plurality of second pad extension portions extending from said second pad connection portion toward said first pad, projections of said second grooves on said imaginary plane falling between projections of said first pad extension portions and projections of said second pad extension portions on said imaginary plane.

2. The light-emitting device as claimed in claim 1, further comprising a first connection electrode and a second connection electrode, said first connection electrode extending into said first grooves to be electrically connected to said first semiconductor layer, said second connection electrode extending into said second grooves to be electrically connected to said second semiconductor layer.

3. The light-emitting device as claimed in claim 2, wherein said second connection electrode includes a second electrode connection portion and a plurality of second electrode extension portions extending from said second electrode connection portion toward said first connection electrode, said projections of said second grooves on said imaginary plane falling within projections of said second electrode extension portions on said imaginary plane.

4. The light-emitting device as claimed in claim 1, wherein said holes are distributed in a first direction and a second direction that is perpendicular to said first direction to form a matrix, said first pad connection portion extending in said first direction, said first pad extension portions extending from said first pad connection portion toward said second metal pad in said second direction.

5. The light-emitting device as claimed in claim 4, wherein said holes form a plurality of rows in said first direction and a plurality of columns in said second direction, said second grooves non-overlapping said rows and said columns of said holes.

6. The light-emitting device as claimed in claim 5, wherein said columns of said holes are located between said second pad extension portions.

7. The light-emitting device as claimed in claim 2, further comprising a second insulation layer formed on said first connection electrode and said second connection electrode, said second insulation layer having a third groove that exposes a portion of said first connection electrode, and a fourth groove that exposes a portion of said second connection electrode, a projection said third groove on said imaginary plane falling within a projection of said first connection electrode on said imaginary plane, a projection said fourth groove on said imaginary plane falling within a projection of said second connection electrode on said imaginary plane.

8. The light-emitting device as claimed in claim 1, wherein each of said first pad extension portions has a width greater than a width of each of said second pad extension portions.

9. The light-emitting device as claimed in claim 1, wherein projections of said first grooves on said imaginary plane fall within said projections of said holes on said imaginary plane.

10. The light-emitting device as claimed in claim 2, further comprising a reflection layer and a barrier layer, said reflection layer being disposed on said second semiconductor layer, said barrier layer covering said reflection layer, said first insulation layer covering said barrier layer and exposing a portion of said barrier layer at said second grooves, said second connection electrode extending into said second grooves to be electrically connected to said barrier layer.

11. A light-emitting device, comprising:
a semiconductor epitaxial structure that includes a first semiconductor layer, an active layer, and a second semiconductor layer sequentially stacked in such order in a laminating direction, and that has a plurality of holes penetrating said second semiconductor layer and said active layer and exposing a portion of said first semiconductor layer;
a metal layer that is formed on said second semiconductor layer;
a first insulation layer that is disposed on said semiconductor epitaxial structure, and that has a plurality of first grooves and a plurality of second grooves, said first grooves exposing said portion of said first semiconductor layer, said second groove exposing a part of said metal layer;
a first connection electrode that is formed on said first insulation layer and that extends into said first grooves to be electrically connected to said first semiconductor layer; and
a second connection electrode that extends into said second grooves to be electrically connected to said metal layer;
a second insulation layer that is formed on said first connection electrode and said second connection electrode, and that has a third groove and a fourth groove;
a first pad that is disposed in said third groove and that is electrically connected to said first semiconductor layer; and
a second pad that is disposed in said fourth groove and that is electrically connected to said second semiconductor layer;
wherein projections of said first pad and said second pad on an imaginary plane perpendicular to said laminating direction respectively non-overlap projections of said first grooves and said second grooves on said imaginary plane, and said projections of said second grooves on said imaginary plane fall within a projection of said second connection electrode on said imaginary plane.

12. The light-emitting device as claim in claim 11, wherein said second pad includes a second pad connection portion and a plurality of second pad extension portions extending from said second pad connection portion toward said first pad, projections of said second pad extension portions on said imaginary plane falling within said projection of said second connection electrode, said projections of said second grooves non-overlapping said projections of said second pad extension portions.

13. The light-emitting device as claimed in claim 11, wherein a minimum distance between said first pad and said second pad is no smaller than 150 μm.

14. The light-emitting device as claimed in claim 11, wherein a minimum distance between said first pad and a boundary of said third groove ranges from 5 μm to 20 μm, and a minimum distance between said second metal pad and a boundary of said fourth groove ranges from 5 μm to 20 μm.

15. The light-emitting device as claimed in claim 11, wherein said projection of said first pad occupies 90% to 100% of a projection of said third groove on said imaginary plane, said projection of said second pad occupying 90% to 100% of a projection of said fourth groove on said imaginary plane.

16. A light-emitting device, comprising:
a semiconductor epitaxial structure that includes a first semiconductor layer, an active layer, and a second semiconductor layer sequentially stacked in such order in a laminating direction, and that has a plurality of holes penetrating said second semiconductor layer and said active layer and exposing a portion of said first semiconductor layer;
a first insulation layer that is disposed on said semiconductor epitaxial structure, and that has a plurality of first grooves and a plurality of second grooves, said first grooves penetrating said first insulation layer to expose said first semiconductor layer, said second grooves being formed on said second semiconductor layer and being separated from each other, projections of said second grooves on an imaginary plane perpendicular to said laminating direction being located at a center line of said light-emitting device;
a first connection electrode that is disposed on said first insulation layer and that extends into said first grooves to be electrically connected to said first semiconductor layer;
a second connection electrode that is disposed on said first insulation layer and that is electrically connected to said second semiconductor layer, said first connection electrode and said second connection electrode being separated from each other by a fifth groove;
a first pad that is disposed on said semiconductor epitaxial structure and that is electrically connected to said first semiconductor layer through said first grooves, a projection of said first pad on an imaginary plane perpendicular to said laminating direction non-overlapping projections of said holes on said imaginary plane; and
a second pad that is disposed on said semiconductor epitaxial structure and that is electrically connected to said second semiconductor layer through said second grooves, a projection of said second pad on said imaginary plane non-overlapping said projections of said holes on said imaginary plane.

17. The light-emitting device as claimed in claim 16, wherein an opening of one of said second grooves overlaps a center of said light-emitting device.

18. The light-emitting device as claimed in claim 16, further comprising a second insulation layer that is disposed on said first connection electrode and said second connection electrode, and that has a third groove and a fourth groove, said third groove being formed in said first connection electrode, said fourth groove being formed in said second connection electrode.

19. The light-emitting device as claimed in claim 18, wherein said second insulation layer fills said fifth groove.

20. The light-emitting device as claimed in claim 16, wherein said fifth groove has a continuous ring shape, a minimum distance between said first connection electrode and said second connection electrode being no smaller than 20 μm.
